(19) United States
(12) Patent Application Publication
(10) Pub. No.: US 2026/0242933 A1
(43) Pub. Date: Aug. 20, 2026

(54) DEPOSITION MASK, ELECTRONIC DEVICE MANUFACTURED BY USING THE SAME, AND METHOD FOR MANUFACTURING THE SAME

(71) Applicant: Samsung Display Co., LTD., Yongin-si (KR)

(72) Inventors: Duck Jung LEE, Yongin-si (KR); Sung Woon KIM, Yongin-si (KR); Seung Hun KIM, Yongin-si (KR); Jeong Kuk KIM, Yongin-si (KR); Jun Ho JO, Yongin-si (KR)

(21) Appl. No.: 19/369,866

(22) Filed: Oct. 27, 2025

(30) Foreign Application Priority Data
Feb. 18, 2025 (KR) 10-2025-0020530

(51) Int. Cl. C23C 16/04; B23K 26/38; H10K 59/12; H10K 71/16

(52) U.S. Cl. CPC C23C 16/042; B23K 26/38; H10K 59/12; H10K 71/166

(57) ABSTRACT

A deposition mask includes a mask substrate provided with a cell opening defined therethrough; and an organic film including a support film overlapping the mask substrate and a membrane spaced apart from the support film with a pixel opening therebetween, where the organic film includes an organic material, the mask substrate includes at least one selected from silicon nitride-based, silicon carbide-based, borosilicate-based, silicon oxide-based or aluminum oxide-based material, but a coefficient of thermal expansion of the mask substrate is about zero (0) ppm/° C. or greater and about 3 ppm/° C. or less.

This application claims priority to Korean Patent Application No. 10-2025-0020530, filed on Feb. 18, 2025, and all the benefits accruing therefrom under 35 U.S.C. § 119, the content of which in its entirety is herein incorporated by reference.

### BACKGROUND

### 1. Field

The present disclosure relates to a deposition mask, an electronic device manufactured using the deposition mask, and a method for manufacturing a deposition mask.

### 2. Description of the Related Art

Wearable devices in which a focus is formed at a distance close to user's eyes have been developed in the form of glasses or a helmet. For example, the wearable device may be a head mounted display (HMD) device or augmented reality (AR) glasses. The wearable device may provide an AR screen or a virtual reality (VR) screen to a user.

In the case of wearable devices such as the HMD device or the AR glasses, a display specification of approximately 3500 pixels per inch (PPI) or higher is desired to allow users to use them for a long time without symptoms of dizziness. To this end, organic light emitting diode on silicon (OLEDoS) technology is emerging for use in a high-resolution small organic light emitting display device. The OLEDoS is a technology in which organic light emitting diodes (OLED) are arranged on a semiconductor substrate on which complementary metal oxide semiconductor (CMOS) elements are arranged.

In order to manufacture a display panel with a high resolution of about 3000 PPI or higher, a high-resolution deposition mask may be used.

### SUMMARY

Embodiments of the present disclosure provide a deposition mask that overcomes the problem of low mass productivity, an electronic device manufactured by using the deposition mask, and a method of manufacturing the deposition mask.

However, effects according to the embodiments of the present disclosure are not limited to those exemplified above and various other effects are incorporated herein.

It should be noted that the effects of the present disclosure are not limited to those described above, and other effects of the present disclosure will be apparent from the following description.

In an embodiment of the disclosure, a deposition mask includes a mask substrate provided with a cell opening defined therethrough; and an organic film including a support film overlapping the mask substrate and a membrane spaced apart from the support film with a pixel opening therebetween, where the organic film includes an organic material, the mask substrate includes at least one selected from silicon nitride-based, silicon carbide-based, borosilicate-based, silicon oxide-based or aluminum oxide-based material, and a coefficient of thermal expansion of the mask substrate is about zero (0) parts per million per degree Celsius (ppm/° C.) or greater and about 3 ppm/° C. or less.

In an embodiment, the mask substrate may include an upper surface facing the organic film and a side surface facing the cell opening, and a first inclination angle formed by the side surface and the upper surface is about 50 degrees or greater and about 90 degrees or less.

In an embodiment, the membrane may have a reverse tapered shape, the membrane includes the upper surface located in an opposite direction to a direction where the mask substrate is located and a side surface facing the pixel opening, and a second inclination angle formed by the upper surface and the side surface of the membrane is about 50 degrees or greater and about 80 degrees or less.

In an embodiment, a thickness of the organic film may be about 1 micrometer or greater and about 10 micrometer or less, and the thickness of the organic film has a thickness uniformity of about 10 % or less.

In an embodiment, the organic film may have a light transmittance of about 5% or greater in a visible light range of about 380 nanometers to about 680 nanometers.

In an embodiment, the organic film may include at least one selected from polyvinyl alcohol, polyimide, or acrylic.

In an embodiment, in a plan view, the organic film may be an organic pattern form defining a plurality of pixel openings.

In an embodiment, the support film may include a recessed portion recessed in a direction perpendicular to one surface of the mask substrate, and a portion of the support film overlapping the recessed portion of the support film may not overlap the mask substrate.

In an embodiment of the disclosure, a manufacturing method of a deposition mask, the method includes forming a cell opening by removing a portion of a mask substrate; forming a pixel opening by laser processing after attaching an organic film on the mask substrate; and removing and discarding the organic film after forming a deposition material on a semiconductor substrate.

In an embodiment, in the forming the cell opening by removing the portion of the mask substrate, the mask substrate may include an upper surface facing the organic film and a side surface facing the cell opening, and a first inclination angle formed by the upper surface and the side surface may be about 50 degrees or greater and about 90 degrees or less.

In an embodiment, in the forming of the cell opening by removing the portion of the mask substrate, the mask substrate may include at least one selected from silicon nitride-based, silicon carbide-based, borosilicate-based, silicon oxide-based or aluminum oxide-based material, and a coefficient of thermal expansion of the mask substrate is about zero (0) ppm/° C. or greater and about 3 ppm/° C. or less.

In an embodiment, in the forming of the pixel opening by laser processing after the attaching the organic film on the mask substrate, the mask substrate may be performed by aligning with a master substrate including a light emitting element pattern, and the light emitting element pattern of the mask substrate includes a same alignment as an alignment of an emission area of a display panel.

In an embodiment, the pixel opening may be formed by radiating a laser onto the organic film, the pixel opening may be located at a portion overlapping the light emitting element pattern, and the laser may be radiated from a direction where a lower surface of the mask substrate is located to a direction facing the organic film.

In an embodiment, the cell opening and the pixel opening may be connected to and in communication with each other, and the pixel opening may have a shape of a regular tapered shape or a trapezoidal shape.

In an embodiment, in the forming the pixel opening by laser processing after the attaching the organic film on the mask substrate, the organic film may be divided into a support film overlapping the mask substrate and a membrane spaced apart from the support film with a pixel opening therebetween, the membrane may include an upper surface located in an opposite direction to a direction where the mask substrate is located and a side surface facing the pixel opening, and a second inclination angle formed by the upper surface and the side surface may be about 50 degrees or greater and about 80 degrees or less.

In an embodiment, in the removing and discarding the organic film after the forming the deposition material on the semiconductor substrate, the organic film may be completely removed from the mask substrate, and the mask substrate may be reused after washing and surface treatment processes.

In an embodiment of the disclosure, an electronic device includes a display panel including a deposition material formed by using a deposition mask on a semiconductor substrate; a display device including the display panel; and at least one selected from a processor, a memory, or a power module connected to the display device, where the deposition mask comprises: a mask substrate provided with a cell opening defined therethrough; and an organic film including a support film overlapping the mask substrate, and a membrane spaced apart from the support film with a pixel opening therebetween, the organic film includes an organic material, the mask substrate includes at least one selected from silicon nitride-based, silicon carbide-based, borosilicate-based, silicon oxide-based or aluminum oxide-based material, but a coefficient of thermal expansion of the mask substrate is about zero (0) ppm/° C. or greater and about 3 ppm/° C. or less.

According to embodiments of the present disclosure, it is possible to provide a deposition mask that overcomes the problem of low mass productivity, an electronic device manufactured by using the deposition mask, and a method of manufacturing the deposition mask, by depositing an organic material on a semiconductor substrate by bringing the organic film into contact with a mask substrate, and removing the organic film after the deposition process.

It should be noted that effects of the present disclosure are not limited to those described above and other effects of the present disclosure will be apparent to those skilled in the art from the following descriptions.

### BRIEF DESCRIPTION OF THE DRAWINGS

The above and other features of embodiments of the present disclosure will become more apparent by describing in detail embodiments thereof with reference to the accompanying drawings, in which:

FIG. 1 is a block diagram illustrating an electronic device according to an embodiment;

FIG. 2 is a schematic diagram illustrating examples of the electronic device illustrated in FIG. 1;

FIG. 3 is an exploded perspective view illustrating a display device according to an embodiment;

FIG. 4 is a block diagram illustrating the display device illustrated in FIG. 3;

FIG. 5 is an equivalent circuit diagram illustrating an example of a first sub-pixel illustrated in FIG. 4;

FIG. 6 is a schematic plan view illustrating an example of the display panel illustrated in FIG. 3;

FIG. 7 is a schematic plan view illustrating an example of a display area illustrated in FIG. 6;

FIG. 8 is a schematic enlarged plan view illustrating another example of the display area illustrated in FIG. 6;

FIG. 9 is a schematic cross-sectional view illustrating an example of a display panel taken along line I1-I1′ illustrated in FIG. 7;

FIG. 10 is a schematic cross-sectional view illustrating another example of a display panel taken along line I1-I1′ illustrated in FIG. 7;

FIG. 11 is a schematic perspective view illustrating an example of a head mounted display device;

FIG. 12 is a schematic exploded perspective view illustrating the head mounted display device illustrated in FIG. 11;

FIG. 13 is a schematic perspective view illustrating another example of a head mounted display device;

FIG. 14 is a schematic diagram illustrating a deposition device according to an embodiment;

FIG. 15 is a schematic plan view illustrating a backplane substrate illustrated in FIG. 14;

FIG. 16 is a schematic plan view illustrating a deposition mask illustrated in FIG. 14;

FIG. 17 is a schematic enlarged plane view illustrating mask cell regions illustrated in FIG. 16;

FIG. 18 is a schematic cross-sectional view of a deposition mask of an embodiment taken along line I2-I2′ of FIG. 17;

FIG. 19 is a flowchart showing a manufacturing method of a deposition mask according to an embodiment;

FIGS. 20 and 21 are cross-sectional views showing process S100 of FIG. 19;

FIGS. 22 to 24 are cross-sectional views showing process S200 of FIG. 19;

FIGS. 25 to 27 are cross-sectional views showing process S300 of FIG. 19;

FIG. 28 is a schematic cross-sectional view of a deposition mask according to another embodiment taken along line I2-I2′ of FIG. 17;

FIG. 29 is a flowchart showing a manufacturing method of a deposition mask illustrated in FIG. 28;

FIG. 30 is a cross-sectional view showing process S500 of FIG. 29;

FIGS. 31 and 32 are cross-sectional views showing process S600 of FIG. 29;

FIGS. 33 and 34 are cross-sectional views showing process S700 of FIG. 29;

FIG. 35 is a cross-sectional view showing process S800 of FIG. 29;

FIG. 36 is a schematic cross-sectional view of a deposition mask of another embodiment taken along line I2-I2′ of FIG. 17;

FIG. 37 is a flowchart showing a manufacturing method of a deposition mask illustrated in FIG. 36;

FIGS. 38 and 39 are cross-sectional views showing process S1000 of FIG. 37; and

FIGS. 40 and 41 are cross-sectional views showing process S1100 of FIG. 37.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

Features of various embodiments of the present disclosure may be partially or entirely coupled to or combined with each other, and may be inter-operated and driven in technically various ways. The embodiments may be implemented independently from each other, or may be implemented together in a co-dependent relationship.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the disclosure will be described with reference to the accompanying drawings.

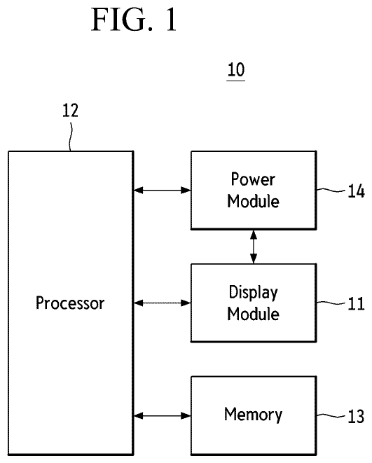

FIG. 1 is a block diagram illustrating an electronic device according to an embodiment.

Referring to FIG. 1, an electronic device 10 according to an embodiment may include a display module 11, a processor 12, a memory 13, a power module 14, and the like.

The processor 12 may include at least one selected from a central processing unit (CPU), an application processor (AP), a graphic processing unit (GPU), a communication processor (CP), an image signal processor (ISP), or a controller.

The memory 13 may store data information used for the operation of the processor 12 or the display module 11. When the processor 12 executes an application stored in the memory 13, an image data signal and/or an input control signal is transmitted to the display module 11, and the display module 11 may process the received signal and output image information through a display screen.

The power module 14 may include a power supply module, such as a power adapter or a battery device, and a power conversion module that converts power supplied by the power supply module to generate power used for the operation of the electronic device 10.

At least one of the components of the electronic device 10 described later may be included in the display device according to the embodiments described above. Further, some of individual modules functionally included in one module may be included in the display device and some others may be provided separately from the display device. In an embodiment, for example, the display device may include the display module 11, and the processor 12, the memory 13, and the power module 14 may be provided in the form of other devices in the electronic device 10 other than the display device.

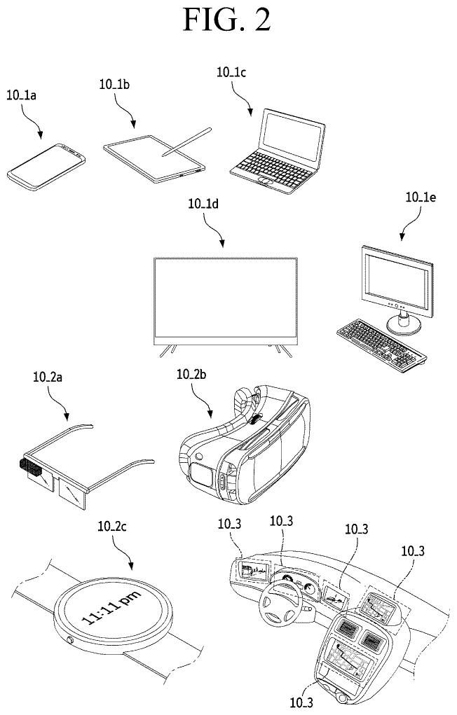

FIG. 2 is a schematic diagram illustrating examples of the electronic device illustrated in FIG. 1.

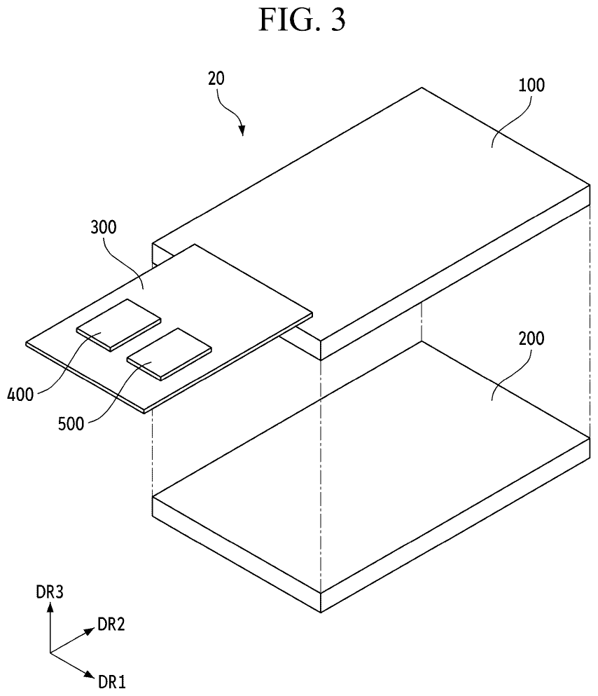

Referring to FIG. 2, various electronic devices 10 to which the display device 20 (see FIG. 3) according to embodiments is applied may include an image display electronic device such as a smartphone 10_1a, a tablet personal computer (PC) 10_1b, a laptop computer 10_1c, a television (TV) 10_1d, and a desk monitor 10_1e. The electronic device 10 to which the display device according to embodiments is applied may be applied to a wearable electronic device including a display module, such as smart glasses 10_2a, a head mounted display 10_2b, or a smart watch 10_2c, and the like. In addition, the electronic device 10 to which the display device according to embodiments is applied may include a vehicle electronic device 10_3 including a display module 11, such as a center fascia, and a dashboard of an automobile, a center information display (CID) placed on the dashboard, a room mirror display, and the like.

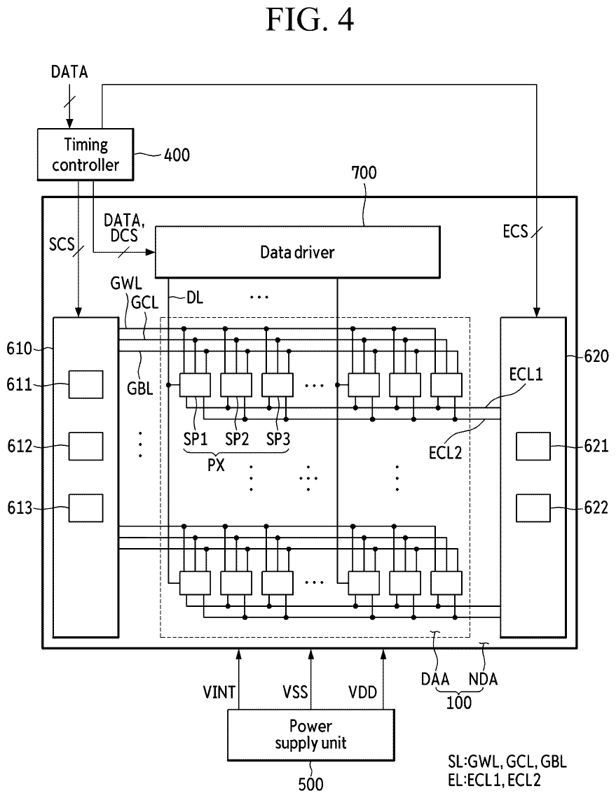

FIG. 3 is an exploded perspective view illustrating a display device according to an embodiment. FIG. 4 is a block diagram illustrating the display device illustrated in FIG. 3.

Referring to FIGS. 3 and 4, a display device 20 according to an embodiment is a device displaying a moving image or a still image. The display device 20 according to an embodiment may be used as the electronic device 10 or the display module 11 of the electronic device 10. In an embodiment, for example, the display device 20 according to an embodiment may be applied to portable electronic devices such as a mobile phone, a smartphone, a tablet personal computer, a mobile communication terminal, an electronic organizer, an electronic book, a portable multimedia player (PMP), a navigation system, an ultra mobile PC (UMPC) or the like. The display device 20 according to an embodiment may be applied as a display module of an electronic device such as a television, a laptop, a monitor, a billboard, or an Internet-of-Things (IoT) terminal. The display device 20 according to an embodiment may be applied to an electronic device such as a smart watch, a watch phone, a head mounted display (HMD) for implementing virtual reality and augmented reality, and the like.

The display device 20 according to an embodiment may include a display panel 100, a heat dissipation layer 200, a circuit board 300, a timing control circuit 400 (or a timing controller), and a power supply circuit 500 (or a power supplier).

The display panel 100 may have a planar shape similar to a quadrilateral shape. In an embodiment, for example, the display panel 100 may have a planar shape similar to a quadrilateral shape, having a short side of a first direction DR1 and a long side of a second direction DR2 intersecting the first direction DR1. In the display panel 100, a corner where a short side in the first direction DR1 and a long side in the second direction DR2 meet may be right-angled or rounded with a predetermined curvature. The planar shape of the display panel 100 is not limited to a quadrilateral shape, and may be a shape similar to another polygonal shape, a circular shape, or an elliptical shape. The planar shape of the display device 20 may conform to the planar shape of the display panel 100, but the present disclosure is not limited thereto.

In an embodiment, as show in FIG. 4, the display panel 100 may include a plurality of pixels PX, a plurality of scan lines SL, a plurality of emission control lines EL, a plurality of data lines DL, a scan driver 610, an emission driver 620, and a data driver 700. The display panel 100 may be divided into a display area DAA for displaying an image and a non-display area NDA in which no image is disposed as shown in FIG. 4.

The plurality of pixels PX may be arranged in the display area DAA. The plurality of pixels PX may be arranged in a matrix form along the first direction DR1 and the second direction DR2. The plurality of scan lines SL and the plurality of emission control lines EL may extend in the first direction DR1, while being arranged in the second direction DR2. The plurality of data lines DL may extend in the second direction DR2, while being arranged in the first direction DR1.

The plurality of scan lines SL may include a plurality of write scan lines GWL, a plurality of control scan lines GCL, and a plurality of bias scan lines GBL. The plurality of emission control lines EL include a plurality of first emission control lines ECL1 and a plurality of second emission control lines ECL2.

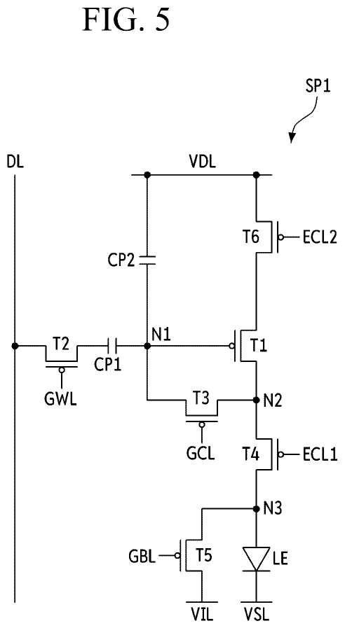

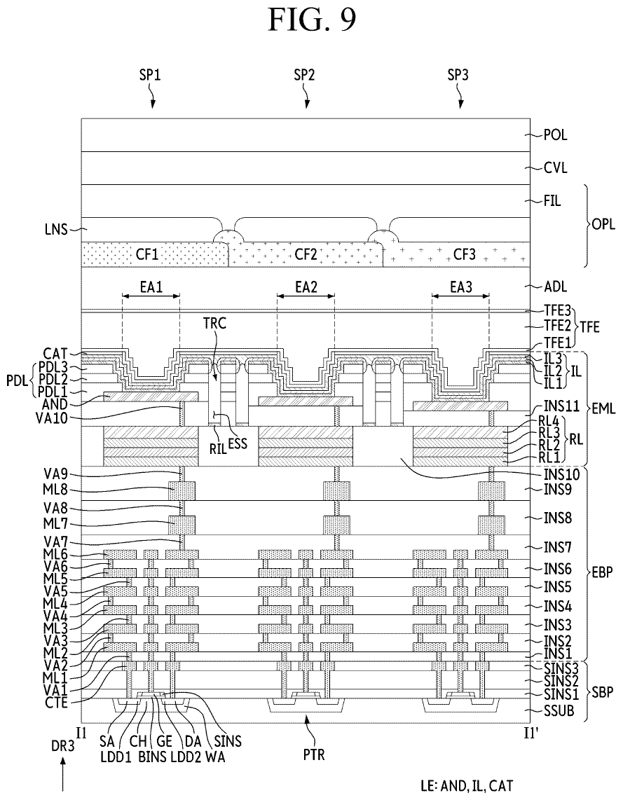

The plurality of pixels PX may include a plurality of sub-pixels SP1, SP2, and SP3. The plurality of sub-pixels SP1, SP2, and SP3 may include a plurality of pixel transistors as shown in FIG. 5, and the plurality of pixel transistors may be formed by a semiconductor process and located on a semiconductor substrate SSUB (see FIG. 9). In an embodiment, for example, the plurality of pixel transistors of the data driver 700 may be formed as complementary metal oxide semiconductor (CMOS) transistors, but the embodiment of the present disclosure is not limited thereto.

Each of the plurality of sub-pixels SP1, SP2, and SP3 may be connected to a corresponding one write scan line GWL of the plurality of write scan lines GWL, a corresponding one control scan line GCL of the plurality of control scan lines GCL, a corresponding one bias scan line GBL of the plurality of bias scan lines GBL, a corresponding one first emission control line ECL1 of the plurality of first emission control lines ECL1, a corresponding one second emission control line ECL2, and one data line DL of the plurality of second emission control lines ECL2. Each of the plurality of sub-pixels SP1, SP2, and SP3 may receive a data voltage of the data line DL in response to a write scan signal of the write scan line GWL, and emit light from the light emitting element according to the data voltage.

The scan driver 610, the emission driver 620, and the data driver 700 may be located in the non-display area NDA.

The scan driver 610 includes a plurality of scan transistors, and the emission driver 620 includes a plurality of light emitting transistors. The plurality of scan transistors and the plurality of light emitting transistors may be formed on the semiconductor substrate SSUB (see FIG. 9) through a semiconductor process. In an embodiment, for example, the plurality of scan transistors and the plurality of light emitting transistors may be formed as CMOS transistors, but the embodiment of the present disclosure is not limited thereto.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from the timing control circuit 400. The write scan signal output unit 611 may generate write scan signals based on the scan timing control signal SCS of the timing control circuit 400 and output the write scan signals sequentially to the write scan lines GWL. The control scan signal output unit 612 may generate control scan signals based on the scan timing control signal SCS and sequentially output the control scan signals to the control scan lines GCL. The bias scan signal output unit 613 may generate bias scan signals according to the scan timing control signal SCS and output them sequentially to the bias scan lines GBL.

The emission driver 620 includes a first emission control driver 621 and a second emission control driver 622. Each of the first emission control driver 621 and the second emission control driver 622 may receive an emission timing control signal ECS from the timing control circuit 400. The first emission control driver 621 may generate first emission control signals based on the emission timing control signal ECS and sequentially output the first emission control signals to the first emission control lines ECL1. The second emission control driver 622 may generate second emission control signals based on the emission timing control signal ECS and sequentially output the second emission control signals to the second emission control lines ECL2.

The data driver 700 may include a plurality of data transistors, and the plurality of data transistors may be formed on the semiconductor substrate SSUB (see FIG. 9) through a semiconductor process. In an embodiment, for example, the plurality of data transistors may be formed as CMOS transistors, but the embodiment of the present disclosure is not limited thereto.

The data driver 700 may receive digital video data DATA and a data timing control signal DCS from the timing control circuit 400. The data driver 700 converts the digital video data DATA into analog data voltages based on the data timing control signal DCS and outputs the analog data voltages to data lines DL. In this case, the sub-pixels SP1, SP2, and SP3 may be selected by the write scan signal of the scan driver 610, and data voltages may be supplied to the selected sub-pixels SP1, SP2, and SP3.

The heat dissipation layer 200 may overlap the display panel 100 in a third direction DR3, which is a thickness direction of the display panel 100. The heat dissipation layer 200 may be located on one surface, e.g., the rear surface, of the display panel 100. The heat dissipation layer 200 serves to dissipate heat generated from the display panel 100. The heat dissipation layer 200 may include a metal layer having high thermal conductivity, such as graphite, silver (Ag), copper (Cu), or aluminum (Al).

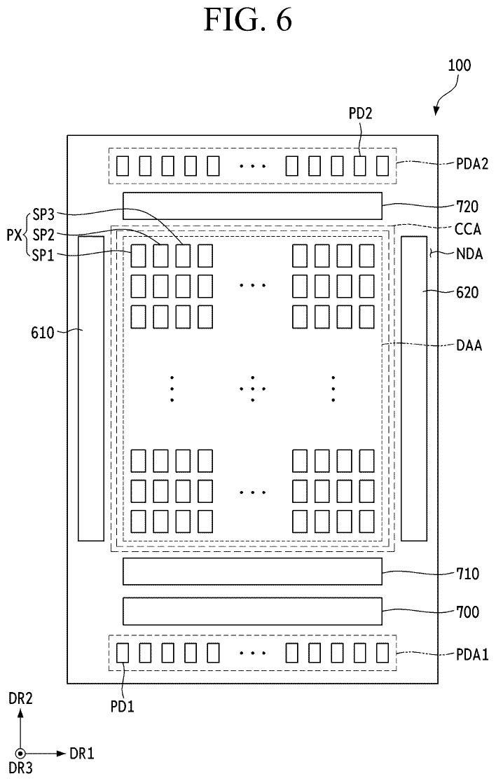

The circuit board 300 may be electrically connected to a plurality of first pads PD1 (see FIG. 6) of a first pad portion PDA1 (see FIG. 6) of the display panel 100 by using a conductive adhesive member such as an anisotropic conductive film. The circuit board 300 may be a flexible printed circuit board with a flexible material, or a flexible film. Although the circuit board 300 is illustrated in FIG. 3 as being unfolded, the circuit board 300 may be bent. In this case, one end of the circuit board 300 may be located on the rear surface of the display panel 100 and/or the rear surface of the heat dissipation layer 200. The other end of the circuit board 300 may be connected to the plurality of first pads PD1 (see FIG. 6) of the first pad portion PDA1 (see FIG. 6) of the display panel 100 by using a conductive adhesive member. One end of the circuit board 300 may be an opposite end of the other end of the circuit board 300.

The timing control circuit 400 may receive digital video data and timing signals inputted from the outside. The timing control circuit 400 may generate the scan timing control signal SCS, the emission timing control signal ECS, and the data timing control signal DCS for controlling the display panel 100 in response to the timing signals. The timing control circuit 400 may output the scan timing control signal SCS to the scan driver 610, and output the emission timing control signal ECS to the emission driver 620. The timing control circuit 400 may output the digital video data and the data timing control signal DCS to the data driver 700.

The power supply circuit 500 may generate a plurality of panel driving voltages according to a power voltage from the outside. In an embodiment, for example, the power supply circuit 500 may generate a first driving voltage VSS, a second driving voltage VDD, and a third driving voltage VINT and supply them to the display panel 100. The first driving voltage VSS, the second driving voltage VDD, and the third driving voltage VINT will be described later in conjunction with FIG. 5.

In an embodiment, each of the timing control circuit 400 and the power supply circuit 500 may be formed as an integrated circuit (IC) and attached to one surface of the circuit board 300. In such an embodiment, the scan timing control signal SCS, the emission timing control signal ECS, the digital video data DATA, and the data timing control signal DCS of the timing control circuit 400 may be supplied to the display panel 100 through the circuit board 300. Further, the first driving voltage VSS, the second driving voltage VDD, and the third driving voltage VINT of the power supply circuit 500 may be supplied to the display panel 100 through the circuit board 300.

In another embodiment, each of the timing control circuit 400 and the power supply circuit 500 may be located in the non-display area NDA of the display panel 100, similarly to the scan driver 610, the emission driver 620, and the data driver 700. In such an embodiment, the timing control circuit 400 may include a plurality of timing transistors, and each power supply circuit 500 may include a plurality of power transistors. The plurality of timing transistors and the plurality of power transistors may be formed on the semiconductor substrate SSUB (see FIG. 9) through a semiconductor process. In an embodiment, for example, the plurality of timing transistors and the plurality of power transistors may be formed as CMOS transistors, but the embodiment of the present disclosure is not limited thereto. Each of the timing control circuit 400 and the power supply circuit 500 may be located between the data driver 700 and the first pad portion PDA1 (see FIG. 6).

FIG. 5 is an equivalent circuit diagram illustrating an example of a first sub-pixel illustrated in FIG. 4.

Referring to FIG. 5, the first sub-pixel SP1 may be connected to the write scan line GWL, the control scan line GCL, the bias scan line GBL, the first emission control line ECL1, the second emission control line ECL2, and the data line DL. Further, the first sub-pixel SP1 may be connected to a first driving voltage line VSL to which the first driving voltage VSS corresponding to a low potential voltage is applied, a second driving voltage line VDL to which the second driving voltage VDD corresponding to a high potential voltage is applied, and a third driving voltage line VIL to which the third driving voltage VINT corresponding to an initialization voltage is applied.

In an embodiment, the first sub-pixel SP1 may include a plurality of transistors T1 to T6, a light emitting element LE, a first capacitor CP1, and a second capacitor CP2.

The light emitting element LE emits light in response to a driving current Ids flowing through the channel of the first transistor T1. The emission amount of the light emitting element LE may be proportional to the driving current. The first electrode of the light emitting element LE may be an anode electrode, and the second electrode of the light emitting element LE may be a cathode electrode. The light emitting element LE may be an organic light emitting diode including a first electrode, a second electrode, and an organic light emitting layer located between the first electrode and the second electrode, but the embodiment of the present disclosure is not limited thereto. In an embodiment, for example, the light emitting element LE may be an inorganic light emitting element including a first electrode, a second electrode, and an inorganic semiconductor located between the first electrode and the second electrode, in which case the light emitting element LE may be a micro light emitting diode.

The first transistor T1 may be a driving transistor that controls a source-drain current Ids (hereinafter referred to as “driving current”) flowing between the source electrode and the drain electrode according to a voltage applied to the gate electrode.

A second transistor T2 may be connected between one electrode of the first capacitor CP1 and the data line DL. The second transistor T2 is turned on by the write scan signal of the write scan line GWL to connect the one electrode of the first capacitor CP1 to the data line DL. Accordingly, the data voltage of the data line DL may be applied to the one electrode of the first capacitor CP1.

A third transistor T3 may be connected between a first node N1 and a second node N2. The third transistor T3 is turned on by the control scan signal of the control scan line GCL to connect the first node N1 to the second node N2. For this reason, when the gate electrode and the source electrode of the first transistor T1 are connected, the first transistor T1 may operate like a diode.

The fourth transistor T4 may be connected between the second node N2 and a third node N3. The fourth transistor T4 is turned on by the first emission control signal of the first emission control line ECL1 to connect the second node N2 to the third node N3. Accordingly, the driving current of the first transistor T1 may be supplied to the light emitting element LE. A fifth transistor T5 may be located between the third node N3 and the third driving voltage line VIL. The fifth transistor T5 is turned on by the bias scan signal of the bias scan line GBL to connect the third node N3 to the third driving voltage line VIL. Accordingly, the third driving voltage VIN of the third driving voltage line VIL may be applied to the first electrode of the light emitting element LE.

The sixth transistor T6 may be connected between the source electrode of the first transistor T1 and the second driving voltage line VDL. The sixth transistor T6 is turned on by the second emission control signal of the second emission control line ECL2 to connect the source electrode of the first transistor T1 to the second driving voltage line VDL. Accordingly, the second driving voltage VDD of the second driving voltage line VDL may be applied to the source electrode of the first transistor T1.

The first capacitor CP1 is connected or formed between the first node N1 and the drain electrode of the second transistor T2. The second capacitor CP2 is formed between the gate electrode of the first transistor T1 and the second driving voltage line VDL.

Each of the first to sixth transistors T1 to T6 may be a metal-oxide-semiconductor field effect transistor (MOSFET). In an embodiment, for example, each of the first to sixth transistors T1 to T6 may be a p-type MOSFET, but the embodiment of the present disclosure is not limited thereto. Each of the first to sixth transistors T1 to T6 may be an n-type MOSFET. Alternatively, some of the first to sixth transistors T1 to T6 may be p-type MOSFETs, and each of the remaining transistors may be an n-type MOSFET.

Although FIG. 5 illustrates an embodiment where the first sub-pixel SP1 includes six transistors T1 to T6 and two capacitors CP1 and CP2, it should be understood that the equivalent circuit diagram of the first sub-pixel SP1 is not limited to that shown in FIG. 5. In an embodiment, for example, the number of transistors and the number of capacitors of the first sub-pixel SP1 are not limited to those shown in FIG. 5.

Further, the equivalent circuit diagram of the second sub-pixel SP2 and the equivalent circuit diagram of the third sub-pixel SP3 may be substantially the same as the equivalent circuit diagram of the first sub-pixel SP1 described in conjunction with FIG. 5. Therefore, any repetitive detailed description of the equivalent circuit diagram of the second sub-pixel SP2 and the equivalent circuit diagram of the third sub-pixel SP3 will be omitted.

FIG. 6 is a schematic plan view illustrating an example of the display panel illustrated in FIG. 3.

Referring to FIG. 6, the display area DAA of the display panel 100 according to an embodiment includes the plurality of pixels PX arranged in a matrix form. The non-display area NDA of the display panel 100 according to an embodiment includes the scan driver 610, the emission driver 620, the data driver 700, a first distribution circuit 710, a second distribution circuit 720, the first pad portion PDA1, and a second pad portion PDA2.

The scan driver 610 may be located on a first side of the display area DAA, and the emission driver 620 may be located on a second side of the display area DAA. In an embodiment, for example, the scan driver 610 may be located on one side of the display area DAA in the first direction DR1, and the emission driver 620 may be located on the other side of the display area DAA in the first direction DR1. However, the embodiment of the present disclosure is not limited thereto, and the scan driver 610 and the emission driver 620 may be located on both the first side and the second side of the display area DAA.

The first pad portion PDA1 may include the plurality of first pads PD1 connected to pads or bumps of the circuit board 300 through a conductive adhesive member. The first pad portion PDA1 may be located on a third side of the display area DAA. In an embodiment, for example, the first pad portion PDA1 may be located on one side of the display area DAA in the second direction DR2. The first pad portion PDA1 may be located outside the data driver 700 in the second direction DR2.

The second pad portion PDA2 may include a plurality of second pads PD2 corresponding to inspection pads that test whether the display panel 100 operates normally. The plurality of second pads PD2 may be connected to a jig or a probe pin during an inspection process, or may be connected to a circuit board for inspection. The circuit board for inspection may be a printed circuit board including a rigid material or a flexible printed circuit board including a flexible material.

The second pad portion PDA2 may be located on a fourth side of the display area DAA. In an embodiment, for example, the second pad portion PDA2 may be located on the other side of the display area DAA in the second direction DR2. The second pad portion PDA2 may be located outside the second distribution circuit 720 in the second direction DR2.

The first distribution circuit 710 distributes data voltages applied through the first pad portion PDA1 to the plurality of data lines DL. In an embodiment, for example, the first distribution circuit 710 may distribute the data voltages applied through one first pad PD1 of the first pad portion PDA1 to the P (P is a positive integer of 2 or more) data lines DL, and as a result, the number of the plurality of first pads PD1 may be reduced. The first distribution circuit 710 may be located on the third side of the display area DAA of the display panel 100. In an embodiment, for example, the first distribution circuit 710 may be located on one side of the display area DAA in the second direction DR2.

The second distribution circuit 720 distributes signals applied through the second pad portion PDA2 to the scan driver 610, the emission driver 620, and the data lines DL. The second pad portion PDA2 and the second distribution circuit 720 may be configured to inspect the operation of each of the pixels PX in the display area DAA. The second distribution circuit 720 may be located on the fourth side of the display area DAA of the display panel 100. In an embodiment, for example, the second distribution circuit 720 may be located on the other side of the display area DAA in the second direction DR2.

A cathode connection portion CCA may be a region in which a second electrode CAT (see FIG. 9) of a display element layer EML (see FIG. 9) is connected to the first driving voltage line VSL of the non-display area NDA. The cathode connection portion CCA may be located outside at least one side of the display area DAA. In an embodiment, for example, the cathode connection portion CCA may be located outside at least on one side among the left side, the right side, the upper side, and the lower side of the display area DAA. Alternatively, the cathode connection portion CCA may be located to surround the display area DAA as shown in FIG. 6 in order to minimize a deviation in the first driving voltage VSS due to a voltage drop (IR drop) or voltage rise (IR rising) of the second electrode CAT in the display area DAA.

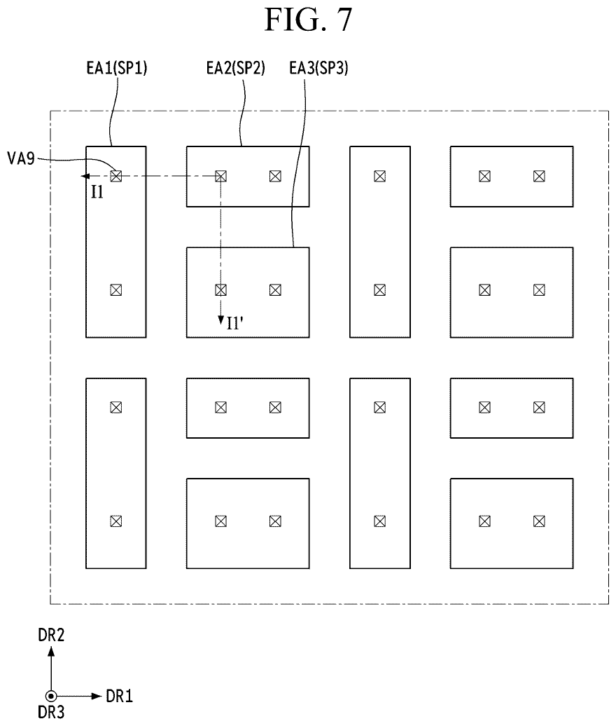

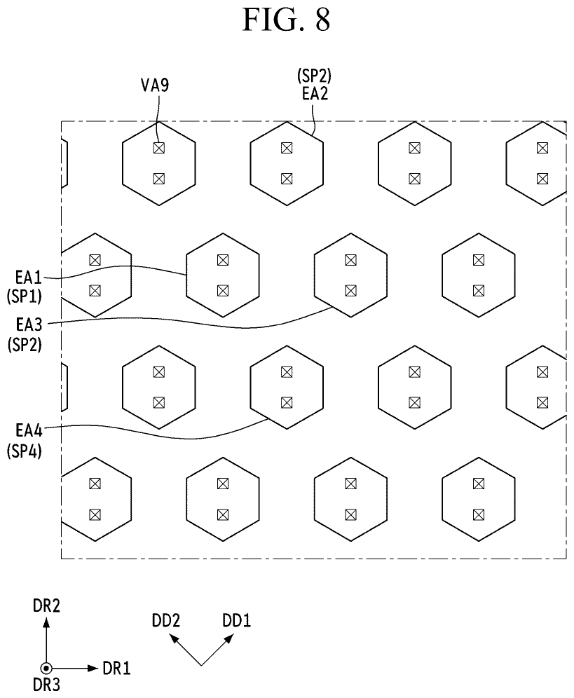

FIG. 7 is a schematic plan view illustrating an example of a display area illustrated in FIG. 6. FIG. 8 is a schematic enlarged plan view illustrating another example of the display area illustrated in FIG. 6.

Referring to FIGS. 7 and 8, each of the pixels PX includes a first emission area EA1 that is an emission area of the first sub-pixel SP1, a second emission area EA2 that is an emission area of the second sub-pixel SP2, and a third emission area EA3 that is an emission area of the third sub-pixel SP3.

The first emission area EA1, the second emission area EA2, and the third emission area EA3 may have, in a plan view (or when viewed in the third direction DR3), a quadrilateral or hexagonal shape as shown in FIGS. 7 and 8, but the present disclosure is not limited thereto. The first emission area EA1, the second emission area EA2, and the third emission area EA3 may have a polygonal shape other than a quadrangle or hexagon, a circular shape, an elliptical shape, or an atypical shape in plan view.

In an embodiment, as shown in FIG. 7, in each of the plurality of pixels PX, the first emission area EA1 and the second emission area EA2 may be adjacent to each other in the first direction DR1. Further, the first emission area EA1 and the third emission area EA3 may be adjacent to each other in the first direction DR1. In addition, the second emission area EA2 and the third emission area EA3 may be adjacent to each other in the second direction DR2. The area of the first emission area EA1, the area of the second emission area EA2, and the area of the third emission area EA3 may be different.

In another embodiment, as shown in FIG. 8, the emission areas EA1, EA2, EA3, and EA4 may have a hexagonal shape in plan view. In such an embodiment, the first emission area EA1 and the third emission area EA3 may be adjacent in the first direction DR1, and the second emission area EA2 and the fourth emission area EA4 may be adjacent in the second direction DR2. Additionally, the first emission area EA1 and the second emission area EA2 may be adjacent in a first diagonal direction DD1, and the second emission area EA2 and the third emission area EA3 may be adjacent in a second diagonal direction DD2. Additionally, the first emission area EA1 and the fourth emission area EA4 may be adjacent in the second diagonal direction DD2, and the third emission area EA3 and the fourth emission area EA4 may be adjacent in the first diagonal direction DD1. The first diagonal direction DD1 may be a direction between the first direction DR1 and the second direction DR2, and may refer to a direction inclined by about 45 degrees with respect to the first direction DR1 and the second direction DR2, and the second diagonal direction DD2 may be a direction perpendicular to the first diagonal direction DD1.

The first sub-pixel SP1 may emit first light, the second sub-pixel SP2 may emit second light, and the third sub-pixel SP3 may emit third light. In an embodiment, for example, the first light may be light of a blue wavelength band, the second light may be light of a green wavelength band, and the third light may be light of a red wavelength band. In an embodiment, for example, the blue wavelength band may be a wavelength band of light whose main peak wavelength is in a range of about 370 nanometers (nm) to about 460 nm, the green wavelength band may be a wavelength band of light whose main peak wavelength is in a range of about 480 nm to about 560 nm, and the red wavelength band may be a wavelength band of light whose main peak wavelength is in the range of about 600 nm to about 750 nm.

Each of the plurality of pixels PX may include three emission areas EA1, EA2, and EA3 as shown in FIG. 7, or may include four emission areas EA1, EA2, EA3, and EA4 as shown in FIG. 8. In this case, the fourth emission area EA4 may emit the same second light as the second emission area EA2, but the present disclosure is not limited thereto.

The emission areas of the plurality of pixels PX may be arranged in a stripe structure in which the emission areas are arranged in the first direction DR1, a PenTile® structure in which the emission areas EA1, EA2, EA3, and EA4 are arranged in a rhombus shape, or a hexagonal structure in which the emission areas each having a hexagonal shape are arranged as shown in FIG. 8.

FIG. 9 is a schematic cross-sectional view illustrating an example of a display panel taken along line I1-I1′ illustrated in FIG. 7.

Referring to FIG. 9, an embodiment of the display panel 100 includes a semiconductor backplane SBP, a light emitting element backplane EBP, the display element layer EML, an encapsulation layer TFE, an optical layer OPL, a cover layer CVL, and a polarizing plate POL.

The semiconductor backplane SBP includes the semiconductor substrate SSUB including a plurality of pixel transistors PTR, a plurality of semiconductor insulating films covering the plurality of pixel transistors PTR, and a plurality of contact terminals CTE electrically connected to the plurality of pixel transistors PTR, respectively. The plurality of pixel transistors PTR may be the first to sixth transistors T1 to T6 described with reference to FIG. 5.

The semiconductor substrate SSUB may be a silicon substrate, a germanium substrate, or a silicon-germanium substrate. The semiconductor substrate SSUB may be a substrate doped with a first type impurity. A plurality of well regions WA may be located on the top surface of the semiconductor substrate SSUB. The plurality of well regions WA may be regions doped with a second type impurity. The second type impurity may be different from the aforementioned first type impurity. In an embodiment, for example, where the first type impurity is a p-type impurity, the second type impurity may be an n-type impurity. In another embodiment, for example, where the first type impurity is an n-type impurity, the second type impurity may be a p-type impurity.

Each of the plurality of well regions WA includes a source region SA corresponding to the source electrode of the pixel transistor PTR, a drain region DA corresponding to the drain electrode, and a channel region CH located between the source region SA and the drain region DA.

A lower insulating film BINS may be located between a gate electrode GE and the well region WA. A side insulating film SINS may be located on the side surface of the gate electrode GE. The side insulating film SINS may be located on the lower insulating film BINS.

Each of the source region SA and the drain region DA may be a region doped with the first type impurity. The gate electrode GE of the pixel transistor PTR may overlap the well region WA in the third direction DR3, which is the thickness direction of the semiconductor substrate SSUB. The channel region CH may overlap the gate electrode GE in the third direction DR3. The source region SA may be located on one side of the gate electrode GE, and the drain region DA may be located on the other side of the gate electrode GE.

Each of the plurality of well regions WA further includes a first low-concentration impurity region LDD1 located between the channel region CH and the source region SA, and a second low-concentration impurity region LDD2 located between the channel region CH and the drain region DA. The first low-concentration impurity region LDD1 may be a region having a lower impurity concentration than the source region SA due to the lower insulating film BINS. The second low-concentration impurity region LDD2 may be a region having a lower impurity concentration than the drain region DA due to the lower insulating film BINS. The distance between the source region SA and the drain region DA may increase due to the first low-concentration impurity region LDD1 and the second low-concentration impurity region LDD2, which may result in an increase of the length of the channel region CH of each of the pixel transistors PTR.

A first semiconductor insulating film SINS1 may be located on the semiconductor substrate SSUB. A second semiconductor insulating film SINS2 may be located on the first semiconductor insulating film SINS1.

The plurality of contact terminals CTE may be located on the second semiconductor insulating film SINS2. Each of the plurality of contact terminals CTE may be connected to a corresponding one of the gate electrode GE, the source region SA, and the drain region DA of each of the pixel transistors PTR through a hole penetrating (formed or defined through) the first semiconductor insulating film SINS1 and the second semiconductor insulating film SINS2. The plurality of contact terminals CTE may include at least one selected from copper (Cu), aluminum (Al), tungsten (W), molybdenum (Mo), chromium (Cr), gold (Au), titanium (Ti), nickel (Ni), and neodymium (Nd), or a combination (e.g., an alloy) thereof.

A third semiconductor insulating film SINS3 may be located on a side surface of each of the plurality of contact terminals CTE. The top surface of each of the plurality of contact terminals CTE may be exposed without being covered by the third semiconductor insulating film SINS3.

Each of the first semiconductor insulating film SINS1, the second semiconductor insulating film SINS2, and the third semiconductor insulating film SINS3 may include silicon carbonitride (SiCN) or a silicon oxide (SiOₓ)-based inorganic film, but the present disclosure is not limited thereto.

In an embodiment, the semiconductor substrate SSUB may be replaced with a glass substrate or a polymer resin substrate such as polyimide. In such an embodiment, thin film transistors may be located on the glass substrate or the polymer resin substrate. The glass substrate may be a rigid substrate that does not bend, and the polymer resin substrate may be a flexible substrate that can be bent or curved.

The light emitting element backplane EBP includes a plurality of conductive layers ML1 to ML8, a plurality of vias VA1 to VA9, and a plurality of interlayer insulating films INS1 to INS9.

The first to ninth interlayer insulating films INS1 to INS9 serve to insulate the first to eighth conductive layers ML1 to ML8. The first to eighth conductive layers ML1 to ML8 serve to connect the plurality of contact terminals CTE exposed from the semiconductor backplane SBP to thereby implement the circuit of the first sub-pixel SP1 shown in FIG. 5.

In an embodiment, for example, the first to sixth transistors T1 to T6 are merely formed in the semiconductor backplane SBP, and the connection of the first to sixth transistors T1 to T6 and the first and second capacitors CP1 and CP2 is accomplished through the first to eighth conductive layers ML1 to ML8. In addition, the connection between the drain region corresponding to the drain electrode of the fourth transistor T4, the source region corresponding to the source electrode of the fifth transistor T5, and a first electrode AND of the light emitting element LE is also accomplished through the first to eighth conductive layers ML1 to ML8.

The first to eighth conductive layers ML1 to ML8 and the first to eighth vias VA1 to VA8 may include substantially the same material as each other. The first to eighth conductive layers ML1 to ML8 and the first to eighth vias VA1 to VA8 may include at least one selected from copper (Cu), aluminum (Al), tungsten (W), molybdenum (Mo), chromium (Cr), gold (Au), titanium (Ti), nickel (Ni), and neodymium (Nd), or a combination (e.g., an alloy) thereof. The first to eighth vias VA1 to VA8 may include substantially the same material as each other. The first to eighth interlayer insulating films INS1 to INS8 may be formed as (or defined by) silicon oxide (SiOₓ)-based inorganic films, but the embodiment of the present disclosure is not limited thereto.

A ninth interlayer insulating film INS9 may be located on the eighth interlayer insulating film INS8 and the eighth conductive layer ML8. The ninth interlayer insulating film INS9 may be formed as a silicon oxide (SiOₓ)-based inorganic film, but the embodiment of the present disclosure is not limited thereto.

Each of the ninth vias VA9 may penetrate the ninth interlayer insulating film INS9 and be connected to the exposed eighth conductive layer ML8. The ninth vias VA9 may include at least one selected from copper (Cu), aluminum (Al), tungsten (W), molybdenum (Mo), chromium (Cr), gold (Au), titanium (Ti), nickel (Ni), and neodymium (Nd), or a combination (e.g., an alloy) thereof.

The display element layer EML may be located on the light emitting element backplane EBP. The display element layer EML may include tenth and eleventh interlayer insulating films INS10 and INS11, reflective electrodes RL, the first electrodes AND, a light emitting stack IL, the second electrode CAT, a pixel defining film PDL, and a plurality of trenches TRC.

The reflective electrodes RL may be located on the ninth interlayer insulating film INS9. The reflective electrodes RL may include at least one or more reflective electrode RL1, RL2, RL3, and RL4. In an embodiment, for example, each of the reflective electrodes RL may include first to fourth reflective electrodes RL1, RL2, RL3, and RL4 as shown in FIG. 9.

The first reflective electrodes RL1 may be located on the ninth interlayer insulating film INS9, and may be connected to the ninth via VA9. Each of the second reflective electrodes RL2 may be located on the first reflective electrode RL1 corresponding thereto. Each of the third reflective electrodes RL3 may be located on the second reflective electrode RL2 corresponding thereto. Each of the fourth reflective electrodes RL4 may be located on the third reflective electrode RL3 corresponding thereto.

Since the second reflective electrode RL2 is an electrode that substantially reflects light from the light emitting elements LE, the thickness of the second reflective electrode RL2 may be greater than the thickness of each of the first reflective electrode RL1, the third reflective electrode RL3, and the fourth reflective electrode RL4.

The first reflective electrodes RL1 may include at least one selected from copper (Cu), aluminum (Al), tungsten (W), molybdenum (Mo), chromium (Cr), gold (Au), titanium (Ti), nickel (Ni), and neodymium (Nd), or a combination (e.g., an alloy) thereof. In an embodiment, for example, the first reflective electrodes RL1 may include titanium nitride (TiN), the second reflective electrodes RL2 may include aluminum (Al), the third reflective electrodes RL3 may include titanium nitride (TiN), and the fourth reflective electrodes RL4 may include titanium (Ti).

The tenth interlayer insulating film INS10 may be located on the ninth interlayer insulating film INS9. The tenth interlayer insulating film INS10 may be located between the reflective electrodes RL adjacent to each other. The tenth interlayer insulating film INS10 may be a film for flattening a stepped portion caused by the reflective electrodes RL. The eleventh interlayer insulating film INS11 may be located on the tenth interlayer insulating film INS10 and the reflective electrodes RL.

The tenth interlayer insulating film INS10 and the eleventh interlayer insulating film INS11 may be formed as silicon oxide (SiOₓ)-based inorganic films, but the embodiment of the present disclosure is not limited thereto.

The eleventh interlayer insulating film INS11 may be an optical auxiliary layer for adjusting the resonance distance of light emitted from the light emitting stack IL in at least one of the first sub-pixel SP1, the second sub-pixel SP2, or the third sub-pixel SP3. The thickness of the eleventh interlayer insulating film INS11 may be different in the first sub-pixel SP1, the second sub-pixel SP2, and the third sub-pixel SP3. That is, in order to adjust a distance from the reflective electrode RL to the second electrode CAT according to a main wavelength of light emitted from each of the first sub-pixel SP1, the second sub-pixel SP2, and the third sub-pixel SP3, the thickness of the eleventh interlayer insulating film INS11 may be set for each of the first sub-pixel SP1, the second sub-pixel SP2, and the third sub-pixel SP3.

In an embodiment, for example, as shown in FIG. 9, the thickness of the eleventh interlayer insulating film INS11 in the first sub-pixel SP1 may be greater than the thickness of the eleventh interlayer insulating film INS11 in the second sub-pixel SP2, and the thickness of the eleventh interlayer insulating film INS11 in the second sub-pixel SP2 may be greater than the thickness of the eleventh interlayer insulating film INS11 in the third sub-pixel SP3. In this case, the distance between the first electrode AND and the reflective electrode RL in the first sub-pixel SP1 is greater than the distance between the first electrode AND and the reflective electrode RL in the second sub-pixel SP2. In addition, the distance between the first electrode AND and the reflective electrode RL in the second sub-pixel SP2 is greater than the distance between the first electrode AND and the reflective electrode RL in the third sub-pixel SP3.

Each of the tenth vias VA10 may penetrate the eleventh interlayer insulating film INS11 and be connected to the exposed fourth reflective electrodes RL4. The tenth vias VA10 may include at least one selected from copper (Cu), aluminum (Al), tungsten (W), molybdenum (Mo), chromium (Cr), gold (Au), titanium (Ti), nickel (Ni), and neodymium (Nd), or a combination (e.g., an alloy) thereof. The thickness of the tenth via VA10 in the first sub-pixel SP1 may be greater than the thickness of the tenth via VA10 in the second sub-pixel SP2, and the thickness of the tenth via VA10 in the second sub-pixel SP2 may be greater than the thickness of the tenth via VA10 in the third sub-pixel SP3.

The first electrode AND of each of the light emitting elements LE may be located on the eleventh interlayer insulating film INS11 and connected to the tenth via VA10. The first electrode AND of each of the light emitting elements LE may be connected to the drain region DA or source region SA of the pixel transistor PTR through the tenth via VA10, the reflective electrode RL, the first to ninth vias VA1 to VA9, the first to eighth metal layers ML1 to ML8, and the contact terminal CTE. The first electrode AND of each of the light emitting elements LE may include at least one selected from copper (Cu), aluminum (Al), tungsten (W), molybdenum (Mo), chromium (Cr), gold (Au), titanium (Ti), nickel (Ni), and neodymium (Nd), or a combination (e.g., an alloy) thereof. In an embodiment, for example, the first electrode AND of each of the light emitting elements LE may be titanium nitride (TiN).

The pixel defining film PDL may be located on a part of the first electrode AND of each of the light emitting elements LE. The pixel defining film PDL may cover the edge of the first electrode AND of each of the light emitting elements LE. The pixel defining film PDL may partition the first emission areas EA1, the second emission areas EA2, and the third emission areas EA3. Each of the first emission area EA1, the second emission area EA2, and the third emission area EA3 may be an area where the light emitting element LE including the first electrode AND, the light emitting stack IL, and the second electrode CAT is located.

The first emission area EA1 may be defined as an area in which the first electrode AND, the light emitting stack IL, and the second electrode CAT are sequentially stacked in the first sub-pixel SP1 to emit light. The second emission area EA2 may be defined as an area in which the first electrode AND, the light emitting stack IL, and the second electrode CAT are sequentially stacked in the second sub-pixel SP2 to emit light. The third emission area EA3 may be defined as an area in which the first electrode AND, the light emitting stack IL, and the second electrode CAT are sequentially stacked in the third sub-pixel SP3 to emit light.

The pixel defining film PDL may include first to third pixel defining films PDL1, PDL2, and PDL3. The first pixel defining film PDL1 may be located on the edge of the first electrode AND of each of the light emitting elements LE, the second pixel defining film PDL2 may be located on the first pixel defining film PDL1, and the third pixel defining film PDL3 may be located on the second pixel defining film PDL2. The first pixel defining film PDL1, the second pixel defining film PDL2, and the third pixel defining film PDL3 may be formed as silicon oxide (SiOₓ)-based inorganic films. Alternatively, the first pixel defining film PDL1 and the third pixel defining film PDL3 may be formed as silicon nitride (SiNₓ)-based inorganic films, whereas the second pixel defining film PDL2 may be formed as a silicon oxide (SiOₓ)-based inorganic film. The first pixel defining film PDL1, the second pixel defining film PDL2, and the third pixel defining film PDL3 may each have a thickness of about 500 Å.

In an embodiment, the first pixel defining film PDL1, the second pixel defining film PDL2, and the third pixel defining film PDL3 may have a cross-sectional structure having a stepped portion such that the likelihood of the first encapsulation inorganic film TFE1 being cut off due to the step coverage may be substantially reduced or effectively prevented. Step coverage refers to the ratio of the degree of thin film coated on an inclined portion to the degree of thin film coated on a flat portion. The lower the step coverage, the more likely it is that the thin film will be cut off at inclined portions.

Each of the plurality of trenches TRC may penetrate or extend through the first pixel defining film PDL1, the second pixel defining film PDL2, and the third pixel defining film PDL3. The eleventh interlayer insulating film INS11 may be at least partially recessed at each of the plurality of trenches TRC.

At least one trench TRC may be located between the neighboring sub-pixels SP1, SP2, and SP3. Although FIG. 9 illustrates an embodiment where two trenches TRC are located between the neighboring sub-pixels SP1, SP2, and SP3, the present disclosure is not limited thereto.

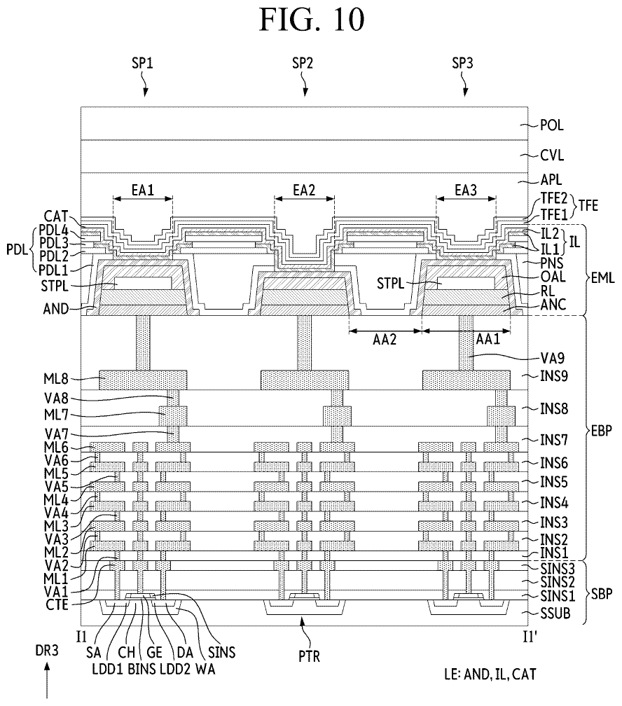

The light emitting stack IL may include a plurality of stack layers IL1, IL2, and IL3. FIG. 9 illustrates an embodiment where the light emitting stack IL has a three-tandem structure including a first stack layer IL1, a second stack layer IL2, and a third stack layer IL3, but the present disclosure is not limited thereto. In another embodiment, for example, the light emitting stack IL may have a two-tandem structure including two stack layers as shown in FIG. 10.

In an embodiment having the three-tandem structure, the light emitting stack IL may have a tandem structure including a plurality of stack layers IL1, IL2, and IL3 that emit different lights. In an embodiment, for example, the light emitting stack IL may include the first stack layer IL1 that emits the first light, the second stack layer IL2 that emits the second light, and the third stack layer IL3 that emits the third light. The first stack layer IL1, the second stack layer IL2, and the third stack layer IL3 may be sequentially stacked.

The first stack layer IL1 may have a structure in which a first hole transport layer, a first light emitting layer that emits the first light, and a first electron transport layer are sequentially stacked. The second stack layer IL2 may have a structure in which a second hole transport layer, a second light emitting layer that emits the second light, and a second electron transport layer are sequentially stacked. The third stack layer IL3 may have a structure in which a third hole transport layer, a third light emitting layer that emits the third light, and a third electron transport layer are sequentially stacked.

A first charge generation layer for supplying charges to the second stack layer IL2 and supplying electrons to the first stack layer IL1 may be located between the first stack layer IL1 and the second stack layer IL2. The first charge generation layer may include an n-type charge generation layer that supplies electrons to the first stack layer IL1 and a p-type charge generation layer that supplies holes to the second stack layer IL2. The n-type charge generation layer may include a dopant of a metal material.

A second charge generation layer for supplying charges to the third stack layer IL3 and supplying electrons to the second stack layer IL2 may be located between the second stack layer IL2 and the third stack layer IL3. The second charge generation layer may include an n-type charge generation layer that supplies electrons to the second stack layer IL2 and a p-type charge generation layer that supplies holes to the third stack layer IL3.

The first stack layer IL1 may be located on the first electrodes AND and the pixel defining film PDL, and an organic pattern RIL located on the bottom surface of each trench TRC may be the same material as the first stack layer IL1. Due to the trench TRC, the first stack layer IL1 may be cut off between the neighboring sub-pixels SP1, SP2, and SP3. The second stack layer IL2 may be located on the first stack layer IL1. Due to the trench TRC, the second stack layer IL2 may be cut off between the neighboring sub-pixels SP1, SP2, and SP3. An empty space ESS may be located between the organic pattern RIL and the second stack layer IL2 in the trench TRC. The third stack layer IL3 may be located on the second stack layer IL2. The third stack layer IL3 is not cut off by the trench TRC and may be located to cover the second stack layer IL2 in each of the trenches TRC.

In an embodiment having the three-tandem structure, each of the plurality of trenches TRC may be a structure for cutting off the first to third hole transport layers, the first charge generation layer, and the second charge generation layer of the first to third stack layers IL1, IL2, and IL3 of the display element layer EML between the neighboring sub-pixels SP1, SP2, and SP3. In an embodiment having the two-tandem structure, each of the plurality of trenches TRC may be a structure for cutting off the charge generation layer and the lower stack layer located between the lower stack layer and the upper stack layer.

In order to stably cut off the first and second stack layers IL1 and IL2 of the display element layer EML between the neighboring sub-pixels SP1, SP2, and SP3, the height of each of the plurality of trenches TRC may be greater than the height of the pixel defining film PDL. The height of each of the plurality of trenches TRC refers to the length of each of the plurality of trenches TRC in the third direction DR3. The height of the pixel defining film PDL refers to the length of the pixel defining film PDL in the third direction DR3. In order to cut off the charge generation layers and the hole transport layers of the light emitting stack IL of the display element layer EML between the neighboring sub-pixels SP1, SP2, and SP3, a different structure may be present instead of the trench TRC. For example, instead of the trench TRC, a reverse tapered partition wall may be located on the pixel defining film PDL.

In addition, FIG. 9 illustrates an embodiment where the light emitting stack IL that emits light is located in the first emission area EA1, the second emission area EA2, and the third emission area EA3, but the present disclosure is not limited thereto. In another embodiment, for example, instead of the light emitting stack IL, the first light emitting layer may be located in the first emission area EA1, and may be omitted from the second emission area EA2 and the third emission area EA3. Furthermore, the second light emitting layer may be located in the second emission area EA2 and may be omitted from the first emission area EA1 and the third emission area EA3. Furthermore, the third light emitting layer may be located in the third emission area EA3 and may be omitted from the first emission area EA1 and the second emission area EA2. In this case, first to third color filters CF1, CF2, and CF3 of the optical layer OPL may be omitted.

The second electrode CAT may be located on the light emitting stack IL. That is, the second electrode CAT may be located on the third stack layer IL3. The second electrode CAT may include a transparent conductive material (TCO) such as ITO or IZO that can transmit light or a semi-transmissive conductive material such as magnesium (Mg), silver (Ag), or an alloy of magnesium (Mg) and silver (Ag). In an embodiment where the second electrode CAT includes a semi-transmissive conductive material, the light emission efficiency may be improved in each of the first to third sub-pixels SP1, SP2, and SP3 due to a micro-cavity effect.

The encapsulation layer TFE may be located on the display element layer EML. The encapsulation layer TFE may include at least one inorganic film TFE1 and TFE3 to reduce or prevent oxygen or moisture from permeating into the display element layer EML. The first encapsulation inorganic film TFE1 may be located on the second electrode CAT, and the second encapsulation inorganic film TFE3 may be located on the first encapsulation inorganic film TFE1. The first encapsulation inorganic film TFE1 and the second encapsulation inorganic film TFE3 may be formed as multiple films (or to have a multilayered structure) in which one or more inorganic films of silicon nitride (SiNₓ), silicon oxynitride (SiON), silicon oxide (SiOₓ), titanium oxide (TiOₓ), and aluminum oxide (AlOₓ) are alternately stacked.

In addition, the encapsulation layer TFE may include at least one organic film TFE2 to protect the display element layer EML from foreign substances such as dust. The encapsulation organic film TFE2 may be located between the first encapsulation inorganic film TFE1 and the second encapsulation inorganic film TFE3. The organic film TFE2 may be a monomer. Alternatively, organic film TFE2 may be an organic film such as acryl resin, epoxy resin, phenolic resin, polyamide resin, polyimide resin or the like.

An adhesive layer ADL may be a layer for bonding the encapsulation layer TFE to the optical layer OPL. The adhesive layer ADL may be a double-sided adhesive member. In addition, the adhesive layer ADL may be a transparent adhesive member such as a transparent adhesive or a transparent adhesive resin.

The optical layer OPL includes a plurality of color filters CF1, CF2, and CF3, a plurality of lenses LNS, and a filling layer FIL. The plurality of color filters CF1, CF2, and CF3 may include the first to third color filters CF1, CF2, and CF3. The first to third color filters CF1, CF2, and CF3 may be located on the adhesive layer ADL.

The first color filter CF1 may overlap the first emission area EA1 of the first sub-pixel SP1. The first color filter CF1 may transmit light of a first color, i.e., light of a blue wavelength band. The blue wavelength band may be from about 370 nm to about 460 nm. Thus, the first color filter CF1 may transmit light of the first color among light emitted from the first emission area EA1.

The second color filter CF2 may overlap the second emission area EA2 of the second sub-pixel SP2. The second color filter CF2 may transmit light of a second color, i.e., light of a green wavelength band. The green wavelength band may be from about 480 nm to about 560 nm. Thus, the second color filter CF2 may transmit light of the second color among light emitted from the second emission area EA2.

The third color filter CF3 may overlap the third emission area EA3 of the third sub-pixel SP3. The third color filter CF3 may transmit light of a third color, i.e., light of a red wavelength band. The red wavelength band may be from about 600 nm to about 750 nm. Thus, the third color filter CF3 may transmit light of the third color among light emitted from the third emission area EA3.

The plurality of lenses LNS may be located on the first color filter CF1, the second color filter CF2, and the third color filter CF3, respectively. Each of the plurality of lenses LNS may be a structure for increasing the proportion of light directed to the front of the display device 20. Each of the plurality of lenses LNS may have a cross-sectional shape that is convex in an upward direction.

The filling layer FIL may be located on the plurality of lenses LNS. The filling layer FIL may have a selected or predetermined refractive index such that light travels in the third direction DR3 at an interface between the filling layer FIL and the plurality of lenses LNS. Further, the filling layer FIL may be a planarization layer. The filling layer FIL may be an organic film such as acrylic resin, epoxy resin, phenolic resin, polyamide resin, or polyimide resin.

The cover layer CVL may be located on the filling layer FIL. The cover layer CVL may be a glass substrate or a polymer resin. In an embodiment where the cover layer CVL is a glass substrate, the cover layer CVL may be attached onto the filling layer FIL. In this case, the filling layer FIL may serve to bond the cover layer CVL. In an embodiment where the cover layer CVL is a glass substrate, the cover layer CVL may serve as an encapsulation substrate. In an embodiment where the cover layer CVL is a polymer resin, the cover layer CVL may be directly applied onto the filling layer FIL.

The polarizing plate may be located on one surface of the cover layer CVL. The polarizing plate may be a structure for reducing or preventing visibility degradation caused by reflection of external light. The polarizing plate may include a linear polarizing plate and a phase retardation film. In an embodiment, for example, the phase retardation film may be a λ/4 plate (quarter-wave plate), but the embodiment of the present disclosure is not limited thereto. However, when visibility degradation caused by reflection of external light is sufficiently overcome by the first to third color filters CF1, CF2, and CF3, the polarizing plate may be omitted.

FIG. 10 is a schematic cross-sectional view illustrating another example of a display panel taken along line I1-I1′ illustrated in FIG. 7.

The embodiment of FIG. 10 is substantially the same as the embodiment of FIG. 9 except that the first electrode AND of each of the light emitting elements LE is in contact with and electrically connected to the side surface of a connection electrode ANC connected to the eighth conductive layer ML8, the trench TRC is omitted, and instead, the third pixel defining film PDL3 and a fourth pixel defining film PDL4 have an eaves-shaped or mushroom-shaped cross-sectional structure. In description of the embodiment of FIG. 10, any repetitive detailed description of the same or like elements as those described above with reference to FIG. 9 will be omitted.

Referring to FIG. 10, in an embodiment, the plurality of connection electrodes ANC may be respectively located on first portions AA1 of the ninth interlayer insulating film INS9. Each of the plurality of connection electrodes ANC may be located on the first portion AA1 of the ninth interlayer insulating film INS9 corresponding thereto. A plurality of connection electrodes ANC may include at least one selected from copper (Cu), aluminum (Al), tungsten (W), molybdenum (Mo), chromium (Cr), gold (Au), titanium (Ti), nickel (Ni), and neodymium (Nd), a combination (e.g., an alloy) thereof, or a transparent conductive oxide. In an embodiment, for example, the plurality of connection electrodes ANC may include titanium (Ti), titanium nitride (TiN), indium tin oxide (ITO), or indium zinc oxide (IZO), but the present disclosure is limited thereto.

A plurality of reflective electrodes RL may be respectively located on the plurality of connection electrodes ANC. Each of the plurality of reflective electrodes RL may be located on the connection electrode ANC corresponding thereto. The plurality of reflective electrodes RL may include at least one selected from copper (Cu), aluminum (Al), tungsten (W), molybdenum (Mo), chromium (Cr), gold (Au), titanium (Ti), nickel (Ni), and neodymium (Nd), or a combination (e.g., an alloy) thereof. In an embodiment, for example, each of the plurality of reflective electrodes RL may include aluminum (Al) having high reflectivity.

A plurality of optical auxiliary films OAL may be respectively located on the plurality of reflective electrodes RL. Each of the plurality of optical auxiliary films OAL may be located on the reflective electrode RL corresponding thereto. The plurality of optical auxiliary films OAL may be formed as silicon oxide (SiOₓ)-based inorganic films, but the present disclosure is not limited thereto.

In each of the first emission area EA1 and the third emission area EA3, a step layer STPL may be located on the reflective electrode RL, and the optical auxiliary film OAL may be located on the step layer STPL. In the second emission area EA2, only the optical auxiliary film OAL may be located on the reflective electrode RL. The thicknesses of the optical auxiliary film OAL in the first emission area EA1, the second emission area EA2, and the third emission area EA3 may be substantially the same as each other.

Due to the step layer STPL, the distance between the reflective electrode RL and the first electrode AND in the first emission area EA1 and the third emission area EA3 may be greater than the distance between the reflective electrode RL and the first electrode AND in the second emission area EA2. The thickness of the step layer STPL and the thickness of the optical auxiliary film OAL may be set in consideration of the wavelength and resonance distance of light emitted from the first stack layer IL1 of the light emitting stack IL, and the wavelength and resonance distance of light emitted from the second stack layer IL2.

Each of the light emitting elements LE may include the first electrode AND, the light emitting stack IL, and the second electrode CAT.

The first electrode AND of each of the light emitting elements LE may be located on the optical auxiliary film OAL corresponding thereto. Since the connection electrode ANC, the reflective electrode RL, and the optical auxiliary film OAL are sequentially stacked, the first electrode AND of each of the light emitting elements LE may be located on the top surface and the side surface of the optical auxiliary film OAL, the side surface of the reflective electrode RL, and the side surface of the connection electrode ANC. Accordingly, the first electrode AND of each of the light emitting elements LE may be in contact with and electrically connected to the side surface of the reflective electrode RL and the side surface of the connection electrode ANC. Therefore, compared to when the first electrode AND of each of the light emitting elements LE is connected to the reflective electrode RL exposed through a through hole penetrating (defined or formed through) the optical auxiliary film OAL, the number of mask processes may be reduced, thereby lowering manufacturing cost and increasing manufacturing efficiency.

The first electrode AND of each of the light emitting elements LE may be connected to the drain region DA or the source region SA of the pixel transistor PTR through the connection electrode ANC, the first to ninth vias VA1 to VA9, the first to eighth conductive layers ML1 to ML8, and the contact terminal CTE.

The ninth interlayer insulating film INS9 may include the first portion AA1 that overlaps the connection electrode ANC in the third direction DR3 and a second portion AA2 that does not overlap the connection electrode ANC in the third direction DR3. The thickness of the first portion AA1 and the thickness of the second portion AA2 of the ninth interlayer insulating film INS9 may be substantially the same as each other.

Alternatively, the thickness of the first portion AA1 of the ninth interlayer insulating film INS9 may be greater than the thickness of the second portion AA2. In t his case, the side surface of the first portion AA1 of the ninth interlayer insulating film INS9 may be exposed, and the first electrode AND of each of the light emitting elements LE may be located on the exposed side surface of the first portion AA1 of the ninth interlayer insulating film INS9.

The first electrode AND of each of the light emitting elements LE may include at least one selected from copper (Cu), aluminum (Al), tungsten (W), molybdenum (Mo), chromium (Cr), gold (Au), titanium (Ti), nickel (Ni), and neodymium (Nd), a combination (e.g., an alloy) thereof, or a transparent conductive oxide. In an embodiment, for example, the first electrode AND of each of the light emitting elements LE may include titanium nitride (TiN), titanium nitride (TiN), indium tin oxide (ITO), or indium zinc oxide (IZO), but the embodiment of the present disclosure is limited thereto.

The pixel defining film PDL may be located on a part of the first electrode AND of each of the light emitting elements LE. The pixel defining film PDL may cover the edge of the first electrode AND of each of the light emitting elements LE. The pixel defining film PDL may partition the first emission areas EA1, the second emission areas EA2, and the third emission areas EA3.

The pixel defining film PDL may include first to fourth pixel defining films PDL1, PDL2, PDL3, and PDL4.

The first pixel defining film PDL1 may be located on the first electrode AND of each of the light emitting elements LE. In an embodiment, the first pixel defining film PDL1 may cover a part of the top surface of the first electrode AND located on the optical auxiliary film OAL. Further, the first pixel defining film PDL1 may cover the first electrode AND located on the side surface of the connection electrode ANC, the side surface of the reflective electrode RL, and the side surface of the optical auxiliary film OAL. The first pixel defining film PDL1 may be located on the top surface of the second portion AA2 of the ninth interlayer insulating film INS9.

A planarization film PNS is a film for flattening the stepped portion caused by the connection electrode ANC, the reflective electrode RL, and the optical auxiliary film OAL.

The planarization film PNS may be located on the first pixel defining film PDL1 covering the first electrode AND located on the side surface of the connection electrode ANC, the side surface of the reflective electrode RL, and the side surface of the optical auxiliary film OAL. The planarization film PNS may be located on the first pixel defining film PDL1 located on the second portion AA2 of the ninth interlayer insulating film INS9.

The planarization film PNS may be located between the connection electrodes ANC adjacent in the first direction DR1 or the second direction DR2. The planarization film PNS may be located between the reflective electrodes RL adjacent in the first direction DR1 or the second direction DR2. The planarization film PNS may be located between the optical auxiliary films OAL adjacent in the first direction DR1 or the second direction DR2.

The step layer STPL is not present in the second emission area EA2, whereas the step layer STPL is present in each of the first emission area EA1 and the third emission area EA3. Accordingly, the heights of the connection electrode ANC, the reflective electrode RL, and the optical auxiliary film OAL in the second emission area EA2 may be less than the heights of the connection electrode ANC, the reflective electrode RL, the step layer STPL, and the optical auxiliary film OAL in the first emission area EA1 and the third emission area EA3. Therefore, the planarization film PNS may cover the top surface of the first pixel defining film PDL1 located on the top surface of the first electrode AND located in the second emission area EA2.

In an embodiment, the top surface of the planarization film PNS may be flatly connected to the top surface of the first pixel defining film PDL1 located on the top surface of the first electrode AND located in the first emission area EA1 and the third emission area EA3. That is, the planarization film PNS may not cover the top surface of the first pixel defining film PDL1 located on the top surface of the first electrode AND located in each of the first emission area EA1 and the third emission area EA3.

The second pixel defining film PDL2 may be located on the first pixel defining film PDL1 and the planarization film PNS, the third pixel defining film PDL3 may be located on the second pixel defining film PDL2, and the fourth pixel defining film PDL4 may be located on the third pixel defining film PDL3. The first pixel defining film PDL1 and the third pixel defining film PDL3 may be formed as silicon nitride (SiNₓ)-based inorganic films, whereas the second pixel defining film PDL2, the fourth pixel defining film PDL4, and the planarization film PNS may be formed as silicon oxide (SiOₓ)-based inorganic films. The first pixel defining film PDL1 includes a material different from that of the planarization film PNS, and thus may serve as a stopper in a chemical mechanical polishing process for the planarization film PNS.

In an embodiment where the planarization film PNS and the second pixel defining film PDL2 are both formed as silicon oxide (SiOₓ)-based inorganic films, the planarization film PNS and the second pixel defining film PDL2 may be formed as a single film.

Since the length of the third pixel defining film PDL3 in one direction is less than the length of the fourth pixel defining film PDL4 in one direction, the bottom surface of the fourth pixel defining film PDL4 may be exposed without being covered by the third pixel defining film PDL3. In other words, the third pixel defining film PDL3 and the fourth pixel defining film PDL4 may have an eaves-shaped or mushroom-shaped cross-sectional structure.

The light emitting stack IL may be located on the first electrode AND and the pixel defining film PDL. The light emitting stack IL may include the first stack layer IL1 and the second stack layer IL2 that emit different lights. In an embodiment where the light emitting stack IL has a two-tandem structure, one of the first stack layer IL1 and the second stack layer IL2 may emit light that includes the wavelength range of at least one selected from the first light, the second light, and the third light, and the other may emit light that includes the wavelength ranges of the other two lights. In an embodiment, for example, the first stack layer IL1 may emit light that includes the wavelength range of the first light and the wavelength range of the third light, and the second stack layer IL2 may emit light that includes the wavelength range of the second light. In an embodiment, for example, the first light may be light of a blue wavelength band, the second light may be light of a green wavelength band, and the third light may be light of a red wavelength band.

A charge generation layer for supplying charges to the second stack layer IL2 and supplying electrons to the first stack layer IL1 may be located between the first stack layer IL1 and the second stack layer IL2. The charge generation layer may include an n-type charge generation layer that supplies electrons to the first stack layer IL1 and a p-type charge generation layer that supplies holes to the second stack layer IL2. The n-type charge generation layer may include a dopant of a metal material.

The first stack layer IL1 is not formed on the bottom surface of the fourth pixel defining film PDL4 that is exposed without being covered by the third pixel defining film PDL3, and thus may be cut off by the eaves-shaped or mushroom-shaped cross-sectional structure of the third pixel defining film PDL3 and the fourth pixel defining film PDL4. In this case, the first hole transport layer of the first stack layer IL1, and a charge generation layer located between the first stack layer IL1 and the second stack layer IL2 may also be cut off. Further, although FIG. 10 illustrates an embodiment where the second stack layer IL2 is connected without being cut off, the second hole transport layer of the second stack layer IL2 may be cut off, and the second electron transport layer of the second stack layer IL2 may be connected without being cut off. Therefore, it is possible to prevent a leakage current from flowing through the first hole transport layer of the first stack layer IL1, the second hole transport layer of the second stack layer IL2, and the charge generation layer between the adjacent emission areas EA1, EA2, and EA3. Accordingly, it is possible to prevent the light emitting stack IL in the adjacent emission areas EA1, EA2, and EA3 from emitting light other than the originally intended light due to the influence of the above current.

Although FIG. 10 illustrates an embodiment having a two-tandem structure in which the light emitting stack IL includes two stack layers IL1 and IL2, the present disclosure is not limited thereto. In an embodiment, for example, the light emitting stack IL may have a three-tandem structure including three stack layers as shown in FIG. 9. In such an embodiment, the charge generation layer between the first stack layer IL1 and the second stack layer IL2, and the charge generation layer between the second stack layer IL2 and the third stack layer IL3 may be cut off by adjusting the height of the third pixel defining film PDL3. Alternatively, as shown in FIG. 9, the trench TRC penetrating the first pixel defining film PDL1, the second pixel defining film PDL2, and the third pixel defining film PDL3 may be added. In this case, the trench TRC may penetrate at least a part of the ninth interlayer insulating film INS9, but the present disclosure is not limited thereto.

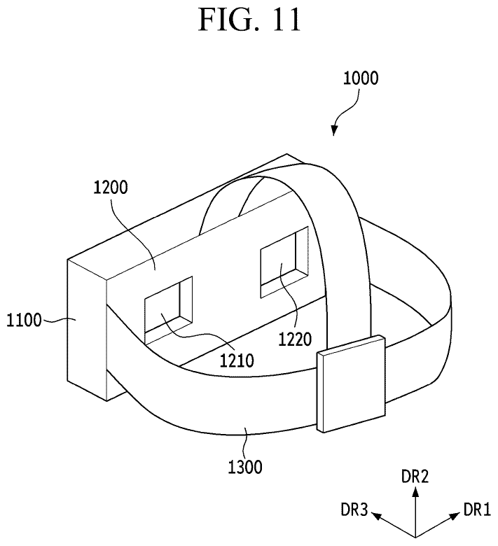

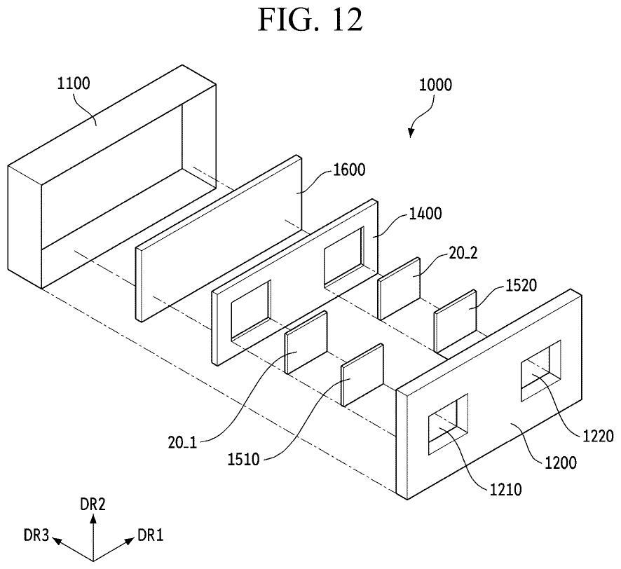

FIG. 11 is a schematic perspective view illustrating an example of a head mounted display device. FIG. 12 is a schematic exploded perspective view illustrating the head mounted display device illustrated in FIG. 11.

Referring to FIGS. 9 and 10, a head mounted display 1000 according to an embodiment includes a first display device 20_1, a second display device 20_2, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

The first display device 20_1 provides an image to the user's left eye, and the second display device 20_2 provides an image to the user's right eye. Since each of the first display device 20_1 and the second display device 20_2 is substantially the same as the display device 20 described in conjunction with FIGS. 3 to 10, any repetitive detailed description of the first display device 20_1 and the second display device 20_2 will be omitted.

The first optical member 1510 may be located between the first display device 20_1 and the first eyepiece 1210. The second optical member 1520 may be located between the second display device 20_2 and the second eyepiece 1220. Each of the first optical member 1510 and the second optical member 1520 may include at least one convex lens.

The middle frame 1400 may be located between the first display device 20_1 and the control circuit board 1600 and between the second display device 20_2 and the control circuit board 1600. The middle frame 1400 serves to support and fix the first display device 20_1, the second display device 20_2, and the control circuit board 1600.

The control circuit board 1600 may be located between the middle frame 1400 and the display device housing 1100. The control circuit board 1600 may be connected to the first display device 20_1 and the second display device 20_2 through the connector. The control circuit board 1600 may convert an image source inputted from the outside into the digital video data, and transmit the digital video data to the first display device 20_1 and the second display device 20_2 through the connector.

The control circuit board 1600 may transmit the digital video data corresponding to a left-eye image optimized for the user's left eye to the first display device 20_1, and may transmit the digital video data corresponding to a right-eye image optimized for the user's right eye to the second display device 20_2. Alternatively, the control circuit board 1600 may transmit the same digital video data to the first display device 20_1 and the second display device 20_2.

The display device housing 1100 serves to accommodate the first display device 20_1, the second display device 20_2, the middle frame 1400, the first optical member 1510, the second optical member 1520, and the control circuit board 1600. The housing cover 1200 is located to cover one open surface of the display device housing 1100. The housing cover 1200 may include the first eyepiece 1210 at which the user's left eye is located and the second eyepiece 1220 at which the user's right eye is located. FIGS. 11 and 12 illustrate an embodiment where the first eyepiece 1210 and the second eyepiece 1220 are located separately, but the present disclosure is not limited thereto. In another embodiment, the first eyepiece 1210 and the second eyepiece 1220 may be combined into one.

The first eyepiece 1210 may be aligned with the first display device 20_1 and the first optical member 1510, and the second eyepiece 1220 may be aligned with the second display device 20_2 and the second optical member 1520. Therefore, the user may view, through the first eyepiece 1210, the image of the first display device 20_1 magnified as a virtual image by the first optical member 1510, and may view, through the second eyepiece 1220, the image of the second display device 20_2 magnified as a virtual image by the second optical member 1520.

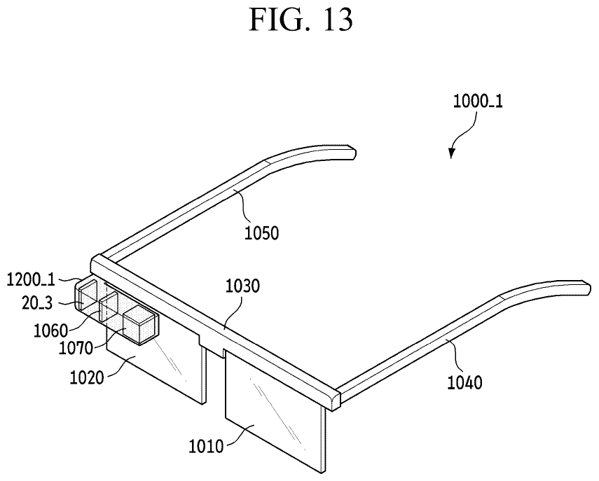

The head mounted band 1300 serves to secure the display device housing 1100 to the user's head such that the first eyepiece 1210 and the second eyepiece 1220 of the housing cover 1200 remain located on the user's left and right eyes, respectively. In an embodiment where the display device housing 1200 is desired to be implemented to be lightweight and compact, the head mounted display 1000 may be provided with, as shown in FIG. 13, an eyeglass frame instead of the head mounted band 1300.

FIG. 13 is a schematic perspective view illustrating another example of a head mounted display device.

Referring to FIG. 13, a head mounted display 1000_1 according to an embodiment may be an eyeglasses-type display device in which a display device housing 1200_1 is implemented in a lightweight and compact manner. The head mounted display 1000_1 according to an embodiment may include a display device 20_3, a left eye lens 1010, a right eye lens 1020, a support frame 1030, temples 1040 and 1050, an optical member 1060, an optical path changing member 1070, and the display device housing 1200_1.

The display device housing 1200_1 may include the display device 20_3, the optical member 1060, and the optical path changing member 1070. The image displayed on the display device 20_3 may be magnified by the optical member 1060, and may be provided to the user's right eye through the right eye lens 1020 after the optical path is changed by the optical path changing member 1070. As a result, the user may view an augmented reality image, through the right eye, in which a virtual image displayed on the display device 20_3 and a real image seen through the right eye lens 1020 are combined.

FIG. 13 illustrates an embodiment where the display device housing 1200_1 is located at the right end of the support frame 1030, but the present disclosure is not limited thereto. In another embodiment, for example, the display device housing 1200_1 may be located at the left end of the support frame 1030, and such an embodiment, the image of the display device 20_3 may be provided to the user's left eye. Alternatively, the display device housing 1200_1 may be located at both the left and right ends of the support frame 1030, and in this case, the user may view the image displayed on the display device 20_3 through both the left and right eyes.

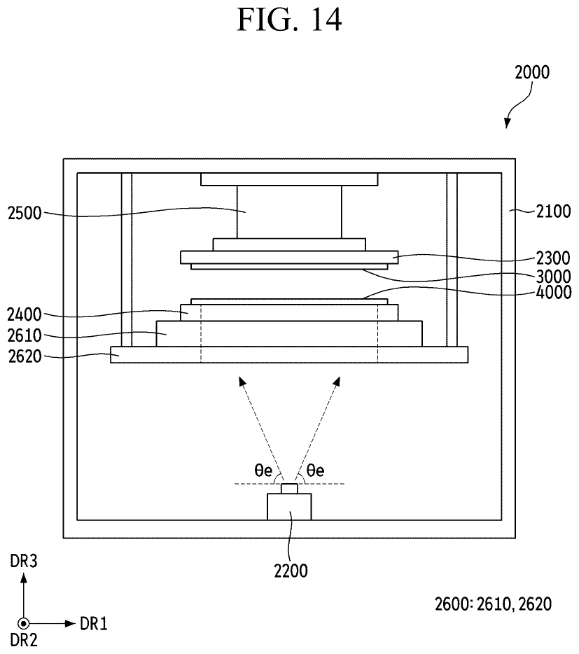

FIG. 14 is a schematic diagram illustrating a deposition device according to an embodiment.

Referring to FIG. 14 in addition to FIGS. 1 to 13, a deposition device 2000 according to an embodiment may be used for forming a deposition material layer on a backplane substrate 3000. For example, the deposition device 2000 according to an embodiment may be used for forming light emitting layers on the backplane substrate 3000 (or a display substrate) in a manufacturing method of the display panel 100 (see FIG. 3). In an embodiment, for example, a semiconductor backplane SBP and a light emitting element backplane EBP may be located on the backplane substrate 3000, and reflective electrodes RL and insulating films INS10 and INS11 may be located on the semiconductor backplane SBP. Electrode patterns, for example, first electrodes AND functioning as anode electrodes and a pixel defining film PDL provided with openings exposing the first electrodes AND may be located on the insulating film INS11 and the first electrodes AND may be electrically connected to the reflective electrodes RL through vias VA10.

The deposition device 2000 may include a deposition source 2200 for providing a vapor deposition material on the backplane substrate 3000, a substrate chuck 2300 supporting the backplane substrate 3000 to face the deposition source 2200, and a mask chuck 2400 located between the deposition source 2200 and the substrate chuck 2300 to support a deposition mask 4000. The deposition source 2200, the substrate chuck 2300, and the mask chuck 2400 may be located inside a process chamber 2100 (or a vapor chamber).

The process chamber 2100 may have an internal space, and a deposition process for forming a deposition material layer on the backplane substrate 3000 may be performed in the internal space of the process chamber 2100. The process chamber 2100 may be connected to a vacuum pump (not shown), and the internal space of the process chamber 2100 may be set to a vacuum atmosphere by the vacuum pump. An opening (not shown) for the carry-in and carry-out of the backplane substrate 3000 and the deposition mask 4000 may be provided in a wall of the process chamber 2100, and the opening may be opened and closed by a gate valve (not shown).

The deposition source 2200 may be located inside the process chamber 2100, and a deposition material may be accommodated in the deposition source 2200. The deposition source 2200 may evaporate a deposition material such as an organic material, an inorganic material, a conductive material, or the like toward the backplane substrate 3000. Although the deposition source 2200 is located on the central portion of the bottom surface of the process chamber 2100 in the drawing, alternatively, the deposition source 2200 may be configured to be moved horizontally by a separate driving unit (not shown).

An organic light emitting material may be sprayed from the deposition source 2200 within a range of deposition incident angle θe, and the sprayed deposition material may be settled on the backplane substrate 3000 through an opening in the deposition mask 4000. In an embodiment, for example, the deposition incident angle θe may be about 85 degrees or greater and less than about 95 degrees, but the present disclosure is not limited thereto.

The substrate chuck 2300 may support the backplane substrate 3000 so that the backplane substrate 3000 faces the deposition source 2200. In an embodiment, for example, the substrate chuck 2300 may be an electrostatic chuck that uses electrostatic force to grip the rear surface of the backplane substrate 3000. In such an embodiment, the electrode patterns, for example, the first electrodes AND may be located on the front surface of the backplane substrate 3000, and the substrate chuck 2300 may grip the rear surface of the backplane substrate 3000 so that the front surface of the backplane substrate 3000 faces downward (for example, faces the deposition source 2200).

The mask chuck 2400 may support the edge portion of the deposition mask 4000. In an embodiment, for example, the mask chuck 2400 may be an electrostatic chuck configured to hold the edge portion of the deposition mask 4000 using an electrostatic force. In particular, the mask chuck 2400 may be provided with a circular opening to expose the deposition mask 4000 toward the deposition source 2200. In an embodiment, for example, the mask chuck 2400 may have a disk shape or a quadrilateral plate shape with a circular opening.

The deposition apparatus 2000 may include a chuck driver for adjusting the position and posture of the backplane substrate 3000 and the deposition mask 4000. In an embodiment, for example, the deposition apparatus 2000 may include a substrate chuck driver 2500 for moving the substrate chuck 2300 and a mask chuck driver 2600 for moving the mask chuck 2400.

The substrate chuck driver 2500 may move the substrate chuck 2300 in the first direction DR1, the second direction DR2, and the third direction DR3 to adjust the position of the backplane substrate 3000. In this case, the first direction DR1 may be the first horizontal direction, the second direction DR2 may be the second horizontal direction perpendicular to the first direction DR1, and the third direction DR3 may be the vertical direction. In an embodiment, for example, the first direction DR1, the second direction DR2, and the third direction DR3 may be an X-axis direction, a Y-axis direction, and a Z-axis direction, respectively.

The substrate chuck driver 2500 may rotate the substrate chuck 2300 around the Z-axis to adjust the azimuth of the backplane substrate 3000, that is, the angle at which the backplane substrate 3000 is held on the bottom surface of the substrate chuck 2300. Further, the substrate chuck driver 2500 may rotate the substrate chuck 2300 around the X-axis, and may also rotate the substrate chuck 2300 around the Y-axis to adjust the inclination of the backplane substrate 3000. In an embodiment, for example, the substrate chuck driver 2500 may include a hexapod actuator 2510 that provides a motion of six degrees of freedom (X, Y, Z, θx, θy, and θz).

The mask chuck driver 2600 may move and rotate the mask chuck 2400 to adjust the horizontal position of the deposition mask 4000 and the azimuth angle of the deposition mask 4000, that is, the angle at which the deposition mask 4000 is placed on the mask chuck 2400. The mask chuck driver 2600 may move the mask chuck 2400 in a direction parallel to the deposition mask 4000 and rotate the mask chuck 2400 with respect to the central axis of the mask chuck 2400. In an embodiment, for example, the mask chuck driver 2600 may move the mask chuck 2400 in the first direction DR1 (X-axis) and the second direction DR2 (Y-axis), and may rotate the mask chuck 2400 with respect to the third direction DR3 (Z-axis). The mask chuck driver 2600 may include, e.g., a piezo actuator 2610 that provides a motion of three degrees of freedom (X, Y, and θz). The piezo actuator 2610 may have an opening communicating with the circular opening of the mask chuck 2400.

The mask chuck driver 2600 may include a mask stage 2620 that is horizontally located in the process chamber 2100 and supports the piezo actuator 2610.

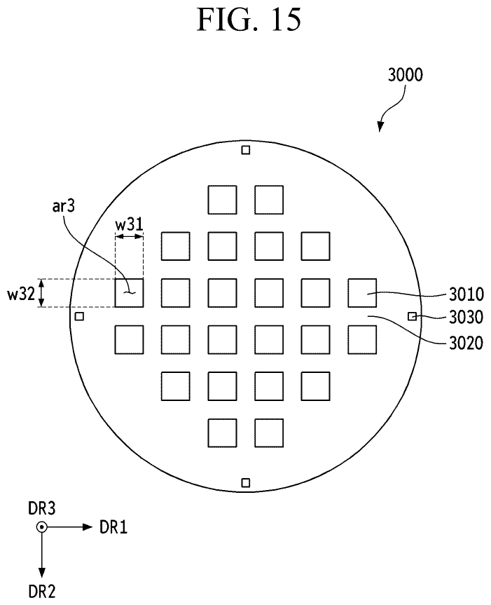

FIG. 15 is a schematic lower view illustrating a backplane substrate illustrated in FIG. 14.

Referring to FIG. 15 in addition to FIGS. 1 to 14, an embodiment of the backplane substrate 3000 may include a plurality of display cell regions 3010 and a scribe lane region 3020 located between the display cell regions 3010. The plurality of display cell regions 3010 may be arranged in a matrix shape along the first direction DR1 and the second direction DR2 and may be individualized into display panels 100 through a dicing process after the display manufacturing process is completed. Each of the display cell regions 3010 may have a right-angled quadrilateral shape as illustrated in FIG. 15 as an example.

Each of the display cell regions 3010 may have a first width w31 in the first direction DR1 and a second width w32 in the second direction DR2. Each of the display cell regions 3010 may have a first area ar3 by the first width w31 and the second width w32.

On the edge of the backplane substrate 3000, substrate alignment keys 3030 may be placed for alignment with the deposition mask 4000. In an embodiment, as illustrated in FIG. 15, four substrate alignment keys 3030 may be aligned on the backplane substrate 3000, but the numbers of the substrate alignment key 3030 may variously modified.

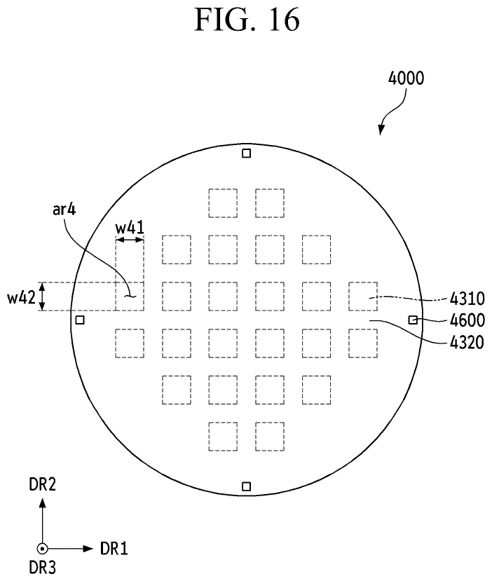

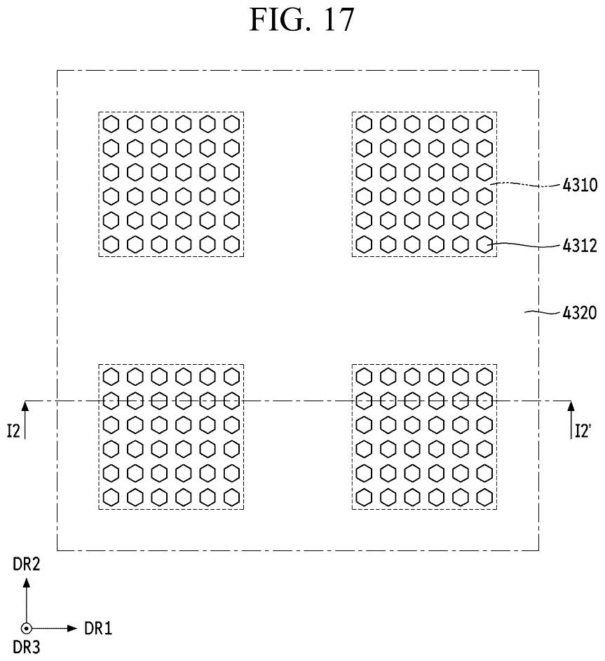

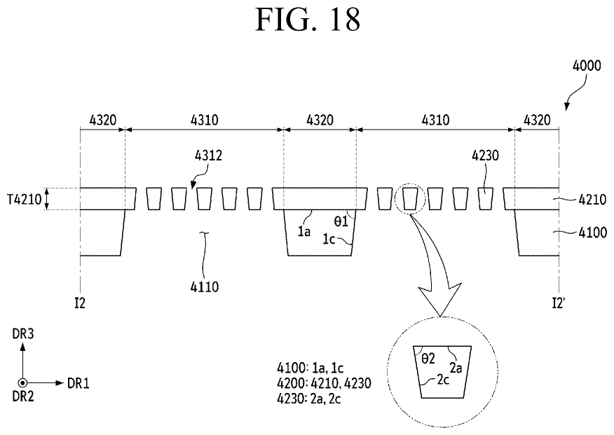

FIG. 16 is a schematic plan view illustrating a deposition mask illustrated in FIG. 14. FIG. 17 is a schematic enlarged plane view illustrating mask cell regions illustrated in FIG. 16. FIG. 18 is a schematic cross-sectional view of a deposition mask of an embodiment taken along line I2-I2′ of FIG. 17.

Referring to FIGS. 14 to 16, an embodiment of the deposition mask 4000 may include a mask cell region 4310, a grid region 4320, and mask key alignment keys 4600.

The mask cell region 4310 may correspond respectively to the display cell regions 3010 of the backplane substrate 3000.

Each mask cell region 4310 may have a first width w41 in the first direction DR1 and a second width w42 in the second direction DR2. Each mask cell region 4310 may have a second area ar4 by the first width w41 and the second width w42.

In an embodiment, the first width w31 of the display cell region 3010 may be smaller than the first width w41 of the mask cell region 4310, and the second width w32 of the display cell region 3010 may be smaller than the second width w42 of the mask cell region 4310. Accordingly, the first area ar3 of the display cell region 3010 may be smaller than the second area ar4 of the mask cell region 4310.

In an embodiment, the sizes of the first width w31 and the second width w32 of the display cell region 3010 may have smaller values than the first width w41 and the second width w42 of the mask cell region 4310 by the size of the Delta function (Δ) of the following <Formula 1>.

$$/ / Δ ( delta function ) = Tan θ ( incident angle ) \times t ( mask thickness ) \qquad < Formula 1 >$$

For example, the incident angle of <Formula 1> may mean a deposition incident angle θe of FIG. 14, and the mask thickness may mean a thickness of the deposition mask 4000 in the third direction DR3.

The deposition mask 4000 according to an embodiment may be formed so that the mask cell region 4310 has a greater width in the first direction DR1 and the second direction DR2 than the display cell region 3010, thereby forming the deposition material on the backplane substrate 3000 without a mask shadow defect by the deposition incident angle θe of the deposition material when forming the deposition material on the backplane substrate 3000 by passing the deposition mask 4000 in the deposition device 2000. The mask shadow defect described above means a defect in which a portion of the deposition material does not pass through due to the deposition mask 4000 and is formed on the deposition mask 4000, thereby effectively preventing a portion of the deposition material from being formed on the backplane substrate 3000. For example, when the above-described mask shadow defect occurs, the thickness of the organic material on the backplane substrate 3000 may become irregular, and due to this, light emission failure may occur.

Moreover, the grid region 4320 may correspond to the scribe lane region 3020 of the backplane substrate 3000, and the mask alignment keys 4600 may correspond to the substrate alignment keys 3030 of the backplane substrate 3000.

In an embodiment, as illustrated in FIG. 17, a plurality of pixel openings 4312 may be formed at a portion overlapping each of the mask cell regions 4310. The plurality of pixel openings 4312 may expose the first electrodes AND of the backplane substrate 3000 in the deposition process and assist the deposition material to be formed on the first electrode AND.

Referring to FIG. 18 in addition to FIGS. 1 to 17, the deposition mask 4000 may include a mask substrate 4100 and an organic film 4200 stacked in the third direction DR3.

The mask substrate 4100 may be located at a portion overlapping the grid region 4320. The mask substrate 4100 may include a cell opening 4110 overlapping the mask cell region 4310, and the mask substrate 4100 may be located to surround the cell opening 4110.

The mask substrate 4100 may be formed in the shape illustrated in the drawing through an etching process or a laser process in the manufacturing process. The manufacturing process will be described below.

The mask substrate 4100 may have a reverse tapered shape or a right-angled quadrilateral shape. In an embodiment, for example, the mask substrate 4100 may include an upper surface 1a facing the organic film 4200 and a side surface 1c. A first inclination angle θ1 formed by the upper surface 1a and the side surface 1c of the mask substrate 4100 may be an acute angle. In an embodiment, for example, the first inclination angle θ1 may be about 50 degrees or greater and about 90 degrees or less.

Since the mask substrate 4100 according to an embodiment has a reverse tapered shape or a right-angled quadrilateral shape, when a deposition material is formed on the backplane substrate 3000 by passing through the deposition mask 4000 in the deposition device 2000, the deposition material may be formed on the backplane substrate 3000 without a mask shadow defect due to the deposition incident angle θe of the deposition material. Any repetitive detailed description thereof will be omitted.

In an embodiment, the mask substrate 4100 may include a silicon-based, silicon nitride-based, silicon carbide-based, silicon oxide-based, or aluminum oxide-based material having a coefficient of thermal expansion (CTE) in a range of about 0 parts per million per degree Celsius (ppm/° C.) or greater and about 3 ppm/° C. or less. In an embodiment, for example, the mask substrate 4100 may include silicon-based glass, borosilicate-based glass, silica-based glass, and ceramic glass. In an embodiment, for example, the borosilicate-based glass may include Pyrex glass (Borofloat).

The above-described coefficient of thermal expansion may be measured using a commonly available thermomechanical analyzer (TMA). In an embodiment, for example, the coefficient of thermal expansion may be measured by adjusting the temperature range from a room temperature to a temperature of about 0 degrees or higher or to a temperature of about 300 degrees or lower, and obtaining the change in length of the mask substrate 4100 in the first direction DR1 and/or the second direction DR2.

Since the mask substrate 4100 according to an embodiment has a coefficient of thermal expansion (CTE) of about zero (0) ppm/° C. or greater and about 3 ppm/° C. or less, the mask substrate 4100 may have high thermal durability even when repeated deposition processes, laser processes, and photo pattern processes are performed. For example, in a case where the mask substrate 4100 has a coefficient of thermal expansion exceeding about 3 ppm/° C., the mask substrate 4100 may be physically deformed during the process, which may cause reliability issues in various display devices 20.

The organic film 4200 may be located on the mask substrate 4100. The organic film 4200 may be located to overlap the mask cell region 4310 and the grid region 4320.

The organic film 4200 may include an organic material. In an embodiment, for example, the organic film 4200 may include all organic materials having a light transmittance of about 5% or greater in the visible light range (about 380 nanometers or greater and 680 nanometers or less). In an embodiment, for example, the organic film 4200 may include at least one selected from polyimide, polyamide, polyamide-imide, polyester, polyethylene, polyvinyl alcohol, and acrylic resin. The above-described light transmittance may be measured using a spectrophotometer (UV-Visible Spectrophotometer).

In an embodiment, a thickness T4210 of the organic film 4200 may be greater than or equal to about 1 micrometer and less than or equal to about 10 micrometers. The above-described thickness T4210 of the organic film 4200 may have a thickness uniformity of about 10% or less. For example, when the thickness T4210 of the organic film 4200 has a value of about 9 micrometers, the thickness T4210 of the organic film 4200 may be formed to be within a range of about 8.1 micrometers to about 9.9 micrometers.

The thickness T4210 range of the above organic film 4200 is a range for movement of the deposition material, stress of the organic film 4200, and appropriate bonding degree between the organic film 4200 and the mask substrate 4100, and when out of the above range, reliability issues of the deposition mask 4000 may be caused during the manufacturing process.

It is illustrated in the drawing that an adhesive is not included between the organic film 4200 and the mask substrate 4100, but the present disclosure is not limited thereto. According to the embodiment, the organic film 4200 may be attached on the mask substrate 4100 using an organic adhesive.

In an embodiment, the organic film 4200 located at a portion overlapping the grid region 4320 may be located on the upper surface 1a of the mask substrate 4100 and be referred to as a support film 4210. The support film 4210 may extend on the mask substrate 4100 and be located even at a portion overlapping the mask cell region 4310.

The organic film 4200 located at a portion overlapping the mask cell region 4310 may be referred to as a membrane 4230. Although the membrane 4230 shown in FIG. 18 is spaced apart from the support film 4210 with the pixel opening 4312 therebetween in a cross-section, it would be understood that the membrane 4230 and the support film 4210 may be a single organic film pattern located to surround the pixel opening 4312 and be integrally formed as a single unitary indivisible part in a plan view.

The pixel opening 4312 and the cell opening 4110 may be located at a portion overlapping the mask cell region 4310. The pixel opening 4312 may be formed by radiating a laser onto the organic film 4200 during the manufacturing process of the deposition mask 4000. The manufacturing process will be described later.

The pixel opening 4312 and the cell opening 4110 may be connected and be in communication. When forming a deposition material on the backplane substrate 3000 by passing through the deposition mask 4000 in the deposition device 2000, the deposition material may pass through the cell opening 4110 and the pixel opening 4312 to be mounted or deposited on the backplane substrate 3000.

In an embodiment, the membrane 4230 may have a reverse tapered shape. The membrane 4230 may have an upper surface 2a and a side surface 2c, and a second inclination angle θ2 formed by the upper surface 2a and the side surface 2c may be an acute angle. In an embodiment, for example, the second inclination angle θ2 may be in a range from about 50 degrees to about 80 degrees. In other words, the pixel opening 4312 according to an embodiment may have a regular tapered shape or a trapezoidal shape.

In the deposition mask 4000 according to an embodiment, by forming the membrane 4230 to have a reverse tapered shape, the shadow defect of the deposition material due to the deposition mask 4000 may be resolved. In other words, in the deposition mask 4000 according to an embodiment, by forming the membrane 4230 to have a reverse tapered shape, a deposition material of uniform thickness may be formed on the backplane substrate 3000 when forming the deposition material on the backplane substrate 3000 by passing through the deposition mask 4000 in the deposition device 2000. Any repetitive detailed description thereof will be omitted.

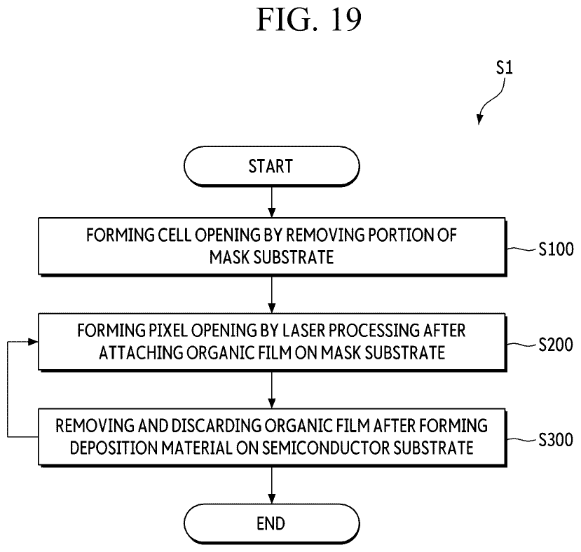

FIG. 19 is a flowchart showing a manufacturing method of a deposition mask according to an embodiment.

Referring to FIG. 19, a manufacturing method S1 of a deposition mask according to an embodiment may include a process of forming a cell opening by removing a portion of a mask substrate (S100), a process of forming a pixel opening by laser processing after attaching an organic film on the mask substrate (S200), and a process of removing and discarding the organic film after forming a deposition material on a semiconductor substrate (S300).

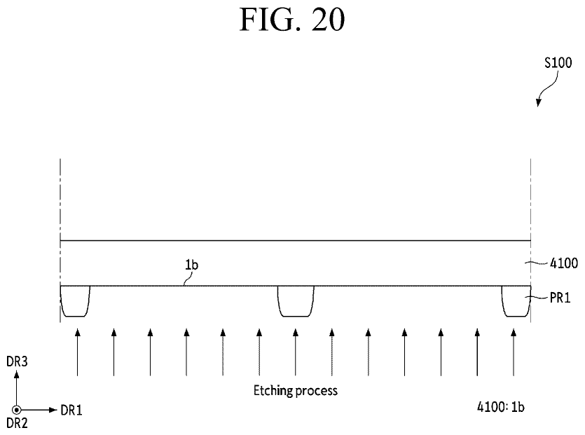

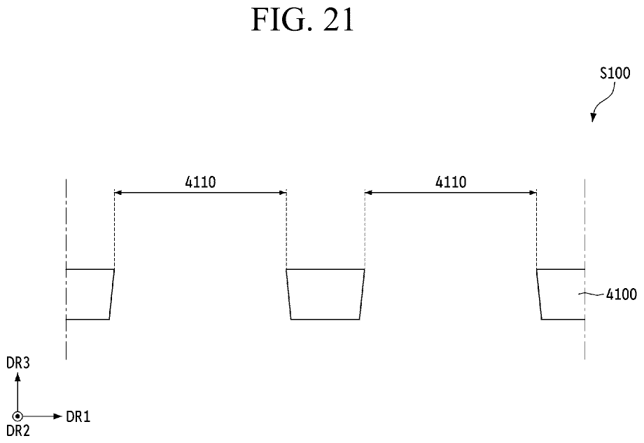

FIGS. 20 and 21 are cross-sectional views showing process S100 of FIG. 19.

The process of forming a cell opening by removing a portion of a mask substrate (S100) will be described with reference to FIGS. 20 and 21.

First, after forming a photoresist PR1 on the lower surface 1b of the mask substrate 4100, an etching process is performed. The present process may be performed using at least one selected from the wet-etching process, the dry-etching process, or the laser processing process depending on the material which the mask substrate 4100 includes.

In an embodiment, for example, where the mask substrate 4100 includes a silicon-based material, the present process may be performed through the wet-etching process using the etchant such as tetramethylammonium hydroxide (TMAH) solution, potassium hydroxide (KOH) solution, and the like.

In another embodiment, for example, where the mask substrate 4100 includes a silicon nitride material, the present process may be performed through the wet-etching process using an etchant such as buffered oxide etchant (BOE), diluted hydrofluoric acid (diluted HF), and the like or a dry-etching process using plasma.

In still another embodiment, for example, the present process may also be performed by a laser etching process without a photoresist.

In the present process, a portion of the mask substrate 4100 may be removed, and accordingly, the mask substrate 4100 may be provided with a cell opening 4110. The mask substrate 4100 may be located to surround the cell opening 4110. In a plan view, the mask substrate 4100 may have one pattern shape including or defining the plurality of cell openings 4110.

In the present process, the mask substrate 4100 may have a tapered angle of a certain range. Any repetitive detailed description of the tapered angle of the mask substrate 4100, which is described above with reference to FIG. 18, will be omitted.

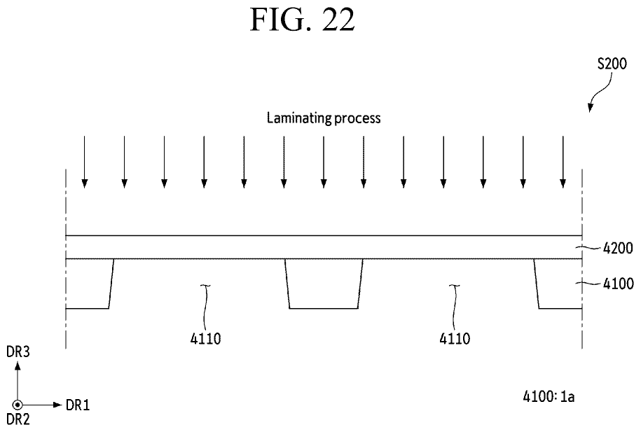

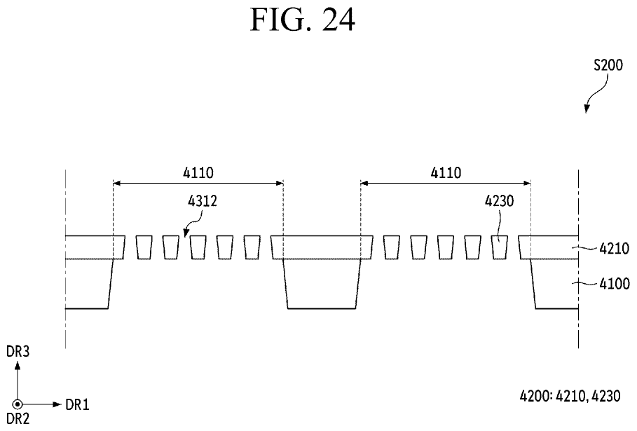

FIGS. 22 to 24 are cross-sectional views showing process S200 of FIG. 19.

Referring to FIGS. 22 to 24, the process of forming a pixel opening by laser processing process after attaching an organic film on the mask substrate (S200) will be described.

First, the organic film 4200 is attached on the upper surface 1a of the mask substrate 4100. The present process may be performed through a laminating process. For example, the laminating process is a method of combining other materials with a film including an organic material, and a strong bond may be formed between the organic film and the other material by applying heat or pressure, using an adhesive, or by radiating with UV light.

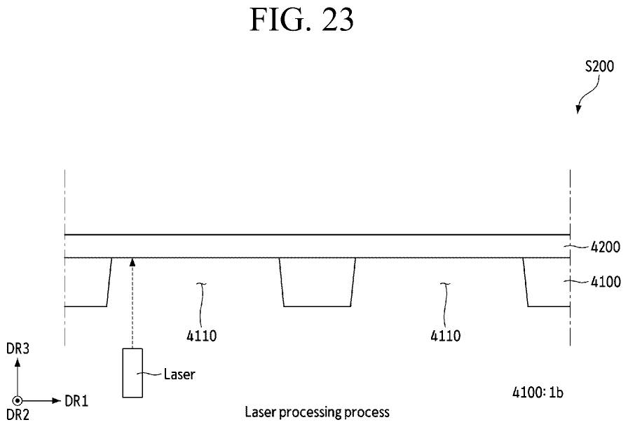

Next, as illustrated in FIG. 23, a laser processing process is performed. The present process may be performed by radiating a laser in the lower surface 1b direction of the mask substrate 4100, that is, the opposite direction of the direction in which the organic film 4200 is located. In the present process, the laser may be radiated onto a portion of the organic film 4200 overlapping the cell opening 4110.

In the present process, the organic film 4200 may be provided with an opening formed by laser irradiation. In the present process, the laser is performed using an auto-focusing apparatus that accurately focuses on a portion of the surface of the organic film 4200, thereby forming accurate patterns and openings. The laser is illustrated as one in the drawing for convenience of description, but the laser may be formed in plural numbers and form a plurality of openings simultaneously in the present process.

In the present process, the shape of the pattern and opening may be formed by adjusting the type, frequency, wavelength, power, and repetition number of the laser. The laser may include ultraviolet, visible, or infrared light. In an embodiment, for example, the laser may be an ArF excimer laser, a KrF excimer laser, a XeCl excimer laser, or a Xe excimer laser. In addition, a gas laser such as a He laser, a He—Cd laser, an Ar laser, a He—Ne laser, or a HF laser may also be used.

In the present process, the plurality of openings provided in the organic film 4200 may have a tapered shape or a trapezoidal shape. The plurality of openings provided in the organic film 4200 in the present process may be referred to as pixel opening 4312 in the present disclosure. As described above, the cell opening 4110 and the pixel opening 4312 may be connected and in communication, and the deposition material may pass through the cell opening 4110 and the pixel opening 4312 and be deposited on the backplane substrate 3000 in the subsequent process.

In the present process, the organic film 4200 may be formed in a form of a support film 4210 positioned to be in contact with the mask substrate 4100 and a membrane 4230 spaced apart from the support film 4210 with the pixel opening 4312 therebetween.

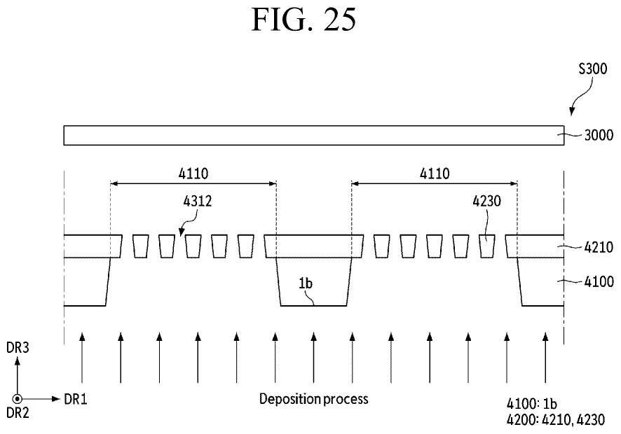

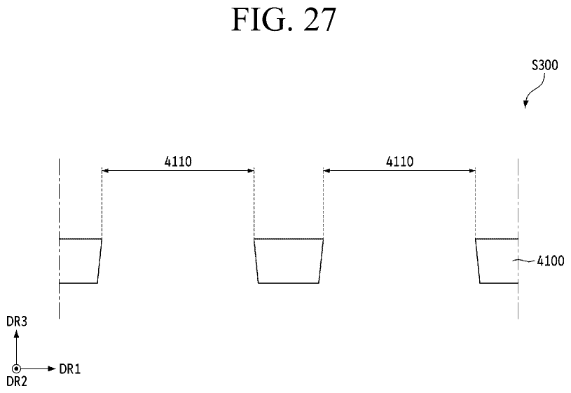

FIGS. 25 to 27 are cross-sectional views showing process S300 of FIG. 19.

The process of removing and discarding the organic film after forming the deposition material on the semiconductor substrate will be described with reference to FIGS. 9 and 25 to 27.

In the present process, the deposition process may be performed in the lower surface 1b direction of the mask substrate 4100. The deposition process may be performed by evaporating a deposition material, such as an organic material, an inorganic material, a conductive material, and the like toward a backplane substrate 3000 using a deposition source 2200 in a deposition device 2000 as shown in FIG. 9. The evaporated deposition material may be deposited on the backplane substrate 3000 through a deposition mask 4000. In an embodiment, for example, the deposition source 2200 may evaporate an organic light emitting material for forming the light emitting layers on the backplane substrate 3000, and a heater (not shown) for evaporating the organic light emitting material may be provided. The evaporated organic light emitting material may be deposited on electrode patterns of the backplane substrate 3000 through the deposition mask 4000, and accordingly, the organic light emitting materials may be formed on the electrode patterns.

As described above, the organic light emitting material may be sprayed from the deposition source 2200 within a range of deposition incident angle θe, and the sprayed deposition material may pass through the cell opening 4110 and the pixel opening 4312 and settle on the backplane substrate 3000.

Since the deposition mask 4000 according to an embodiment includes the pixel opening 4312 of a regular tapered shape, the deposition material may be formed on the backplane substrate 3000 without a shadow defect of the deposition material even when sprayed within the range of the deposition incident angle θe of the deposition material.

In the present process, the deposition mask 4000 may be used repeatedly until the organic film 4200 becomes partially contaminated with the deposition material.

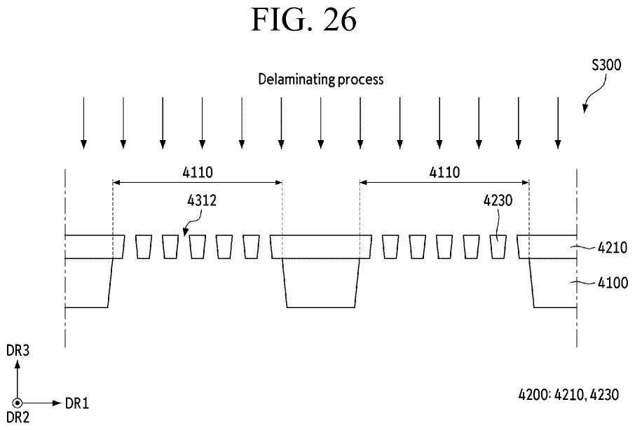

Subsequently, referring to FIG. 26, a delaminating process is performed. The present process may be a process of removing the organic film 4200 from the mask substrate 4100.

The present process may be performed through thermal methods, chemical methods, mechanical methods, laser methods, or the like depending on the unique properties of the organic film 4200. For example, the thermal method is a method of separating the organic film 4200 by applying a specific temperature to the organic film 4200 using a heat plate, an oven, a hot plate and the like, and the chemical method is a method of removing chemical bonds of the organic film 4200 by using a specific solvent (e.g., alkaline cleaning solution, acetone, IPA, NMP, and the like). In addition, the mechanical method is a method of removing the organic film 4200 by applying physical force using a roller, a picker, a peeling device, and the like, and the laser method is a method of removing the organic film 4200 by radiating a laser of a specific wavelength.

In addition to the organic film 4200 removal process described above, the delaminating process may further include subsequent processes such as treatment of residues remaining on the mask substrate 4100, surface treatment of the mask substrate 4100, and drying of the mask substrate 4100 and the like.

Through present process, the organic film 4200 may be completely detached from the mask substrate 4100, and the detached organic film 4200 may be discarded. Through the present process, the mask substrate 4100 including the cell opening 4110 may remain. The remaining mask substrate 4100 may be reused by performing the process of forming the pixel opening by laser processing after attaching the organic film on the mask substrate of FIG. 19.

Referring back to FIGS. 1 to 27, as the deposition mask 4000 according to an embodiment is used in a deposition process by attaching the organic film 4200 on the mask substrate 4100 and, thereafter, reused by detaching the contaminated organic film 4200, there may be effects of ease of manufacturing and reduced manufacturing costs.

Moreover, as the deposition mask 4000 according to an embodiment uses a single mask substrate 4100, there may be effects of ease of manufacturing and reduced manufacturing costs.

In addition, as the deposition mask 4000 according to an embodiment includes a membrane 4230 of a reverse tapered shape, a shadow defect due to the deposition mask 4000 may be minimized in the manufacturing process.

Moreover, as the deposition mask 4000 according to an embodiment has a width greater than the display cell region 3010 of the backplane substrate 3000 in the first direction DR1 and the second direction DR2, a shadow defect due to the deposition mask 4000 may be minimized in the manufacturing process.

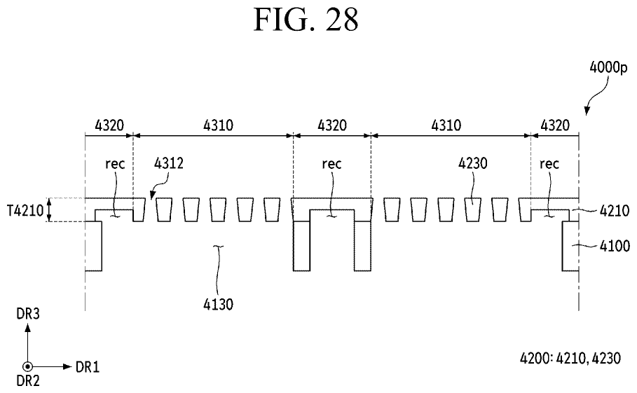

FIG. 28 is a schematic cross-sectional view of a deposition mask according to another embodiment taken along line I2-I2′ of FIG. 17.

Referring to FIG. 28, a deposition mask 4000p may include a mask substrate 4100 and an organic film 4200. The shapes of the mask substrate 4100 and the organic film 4200 included in the deposition mask 4000p may be different from the shapes of the mask substrate 4100 and the organic film 4200 included in the deposition mask 4000.

Hereinafter, any repetitive detailed description of the elements of the deposition mask 4000p which are the same as those of the deposition mask 4000 described above, will be omitted and the differences will be mainly described.

The mask substrate 4100 included in an embodiment of the deposition mask 4000p may be located at a portion overlapping the mask cell region 4310 and the grid region 4320. The mask substrate 4100 included in the deposition mask 4000p may include a cell opening 4130 overlapping the mask cell region 4310 and the grid region 4320. The mask substrate 4100 may be located to surround the cell opening 4130.

The mask substrate 4100 may include a silicon-based, silicon oxide-based, or aluminum oxide-based material having a coefficient of thermal expansion (CTE) of about zero (0) ppm/° C. or greater and about 3 ppm/° C. or less. In an embodiment, for example, the mask substrate 4100 may include at least one selected from silicon-based glass, borosilicate-based glass, silica-based glass, and ceramic glass. Any repetitive detailed description thereof will be omitted.

The organic film 4200 included in the deposition mask 4000p may be located on the mask substrate 4100. The organic film 4200 may be located to overlap the mask cell region 4310 and the grid region 4320.

The organic film 4200 included in the deposition mask 4000p may include the same material as and have the same thickness as the organic film 4200 included in the deposition mask 4000. In an embodiment, for example, the thickness T4210 of the organic film 4200 may be about 1 micrometer or greater and about 10 micrometers or less. Any repetitive detailed description thereof will be omitted.

In an embodiment, the organic film 4200 located at a portion overlapping the grid region 4320 may be located on the mask substrate 4100 and be referred to as a support film 4210. The support film 4210 may be located to overlap the mask substrate 4100.

The support film 4210 included in the deposition mask 4000p may include a recessed portion rec. The recessed portion rec may be located at the central portion of the support film 4210. The recessed portion rec may mean a portion in which a part of the support film 4210 is formed concavely toward one side of the third direction DR3. In an embodiment, for example, the thickness of a portion of the support film 4210 overlapping the recessed portion rec may be smaller than the thickness of a portion of the support film 4210 not overlapping the recessed portion rec. The thickness T4210 of the organic film 4200 described above may mean a thickness of a portion of the support film 4210 not overlapping the recessed portion rec.

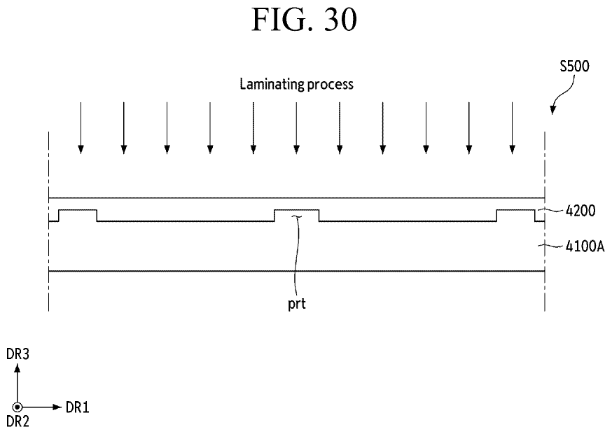

The recessed portion rec of the support film 4320 may be formed by patterning and using the first mask substrate 4100A (see FIG. 30) in the manufacturing process of the deposition mask 4000p. The manufacturing process will be described later.

The mask substrate 4100 included in the deposition mask 4000p may come into contact with the support film 4210 at a portion not overlapping the recessed portion rec of the support film 4210. In other words, the mask substrate 4100 included in the deposition mask 4000p may be located to surround the recessed portion rec of the support film 4210.

The organic film 4200 located at a portion overlapping the mask cell region 4310 may be referred to as a membrane 4230. The membrane 4230 may be spaced apart from the support film 4210 with the pixel opening 4312 therebetween. In a plan view, the membrane 4230 and the support film 4210 may be a single organic film pattern positioned to surround the pixel opening 4312 and may be formed integrally with each other as a single unitary indivisible part. Any repetitive detailed description thereof will be omitted.

The above-described thickness T4210 of the organic film 4200 may be the same as the thickness of the membrane 4230. That is, the thickness of the membrane 4230 and the thickness of the portion of the support film 4210 not overlapping the recessed portion rec may be the same as each other.

The pixel opening 4312 and cell opening 4130 included in the deposition mask 4000p may be located at a portion overlapping the mask cell region 4310. The pixel opening 4312 and the cell opening 4130 may be connected to each other to be in communication with each other.

The membrane 4230 included in the deposition mask 4000p may have the same structure and characteristics as the membrane 4230 included in the deposition mask 4000. In an embodiment, for example, the membrane 4230 included in the deposition mask 4000p may have a reverse taper shape. Any repetitive detailed description thereof will be omitted.

In an embodiment, the deposition mask 4000p may minimize the bonding area between the mask substrate 4100 and the organic film 4200 as the support film 4320 includes the recessed portion rec. Accordingly, the deposition mask 4000p may minimize the detachment defect of the mask substrate 4100 and the organic film 4200 due to the film stress (film strain) of the organic film 4200.

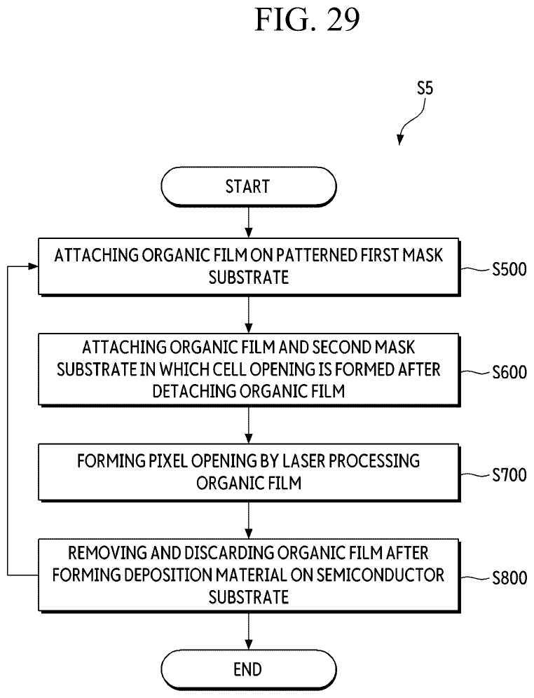

FIG. 29 is a flowchart showing a manufacturing method of a deposition mask according to an embodiment.

Referring to FIG. 29, a manufacturing method S5 of a deposition mask according to an embodiment may include a process of attaching an organic film on a patterned first mask substrate (S500), a process of attaching the organic film and a second mask substrate in which a cell opening is formed after detaching the organic film (S600), a process of forming a pixel opening by laser processing the organic film (S700), and a process of removing and discarding the organic film after forming a deposition material on a semiconductor substrate (S800).

FIG. 30 is a cross-sectional view showing process S500 of FIG. 29.

The process of attaching the organic film on the patterned first mask substrate (S500) will be described with reference to FIG. 30.

First, a patterned first mask substrate 4100A is prepared. The first mask substrate 4100A may include a plurality of protrusion portions prt. The protrusion portion prt may protrude in the third direction DR3, and each of the protrusion portions prt may be spaced apart from each other.

Next, an organic film 4200 is attached on the first mask substrate 4100A. The present process may be performed through a laminating process. Any repetitive detailed description of the laminating process will be omitted.

In the present process, the organic film 4200 may planarize the patterned shape of the first mask substrate 4100A, and be formed in a shape corresponding to the patterned shape of the first mask substrate 4100A. For example, in the present process, the thickness of a portion of the organic film 4200 overlapping the protrusion portion prt of the first mask substrate 4100A may be formed to be relatively thin, and the thickness of a portion of the organic film 4200 not overlapping the protrusion portion prt may be formed to be relatively thick.

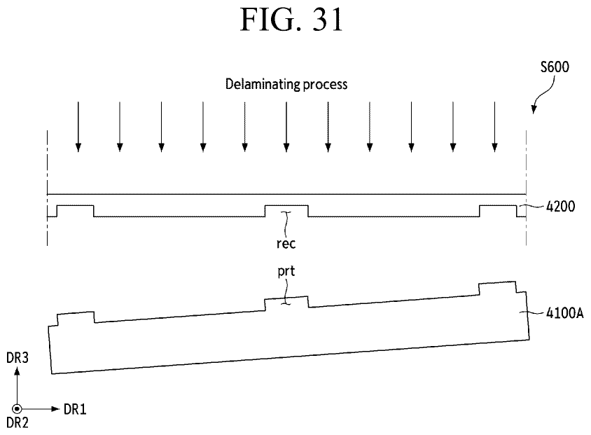

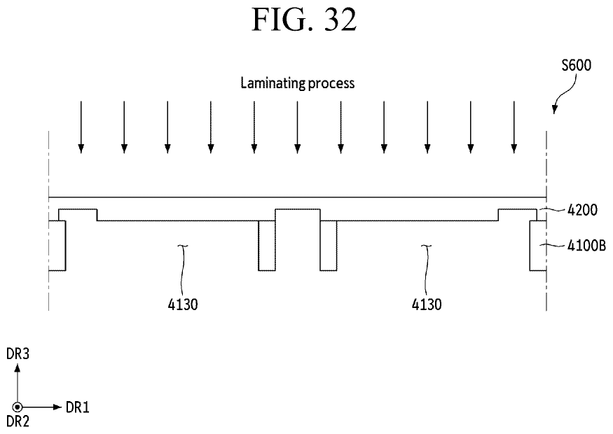

FIGS. 31 and 32 are cross-sectional views showing process S600 of FIG. 29.

The process of attaching the organic film and the second mask substrate in which the cell opening is formed after detaching the organic film (S600) will be described with reference to FIGS. 31 and 32.

First, a delaminating process of the organic film 4200 is performed. In the present process, the organic film 4200 may be separated from the first mask substrate 4100A. In the present process, the organic film 4200 may be detached without any damaged portion.

The delaminating process performed in the present process may be performed through a thermal method, a mechanical method, and a laser method. Any repetitive detailed description thereof will be omitted.

Through the present process, the organic film 4200 may be completely detached from the first mask substrate 4100A, and the shape of the organic film 4200 may remain as the same as the shape before the delaminating process.

In the present process, the first mask substrate 4100A separated from the organic film 4200 may be reused after going through subsequent processes such as residue treatment, surface treatment, and drying.

In the present process, the organic film 4200 may be formed in a shape including a plurality of recessed portions rec. The plurality of recessed portions rec included in the organic film 4200 may be formed to correspond to the plurality of protrusion portions prt included in the first mask substrate 4100A.

Subsequently, a second mask substrate 4100B patterned to have the cell opening 4130 is attached on the organic film 4200. The second mask substrate 4100B may be a different substrate separate from the first mask substrate 4100A. The present process may be performed through a laminating process. Any repetitive detailed description thereof will be omitted.

The second mask substrate 4100B may be referred to as a mask substrate 4100 in FIG. 28.

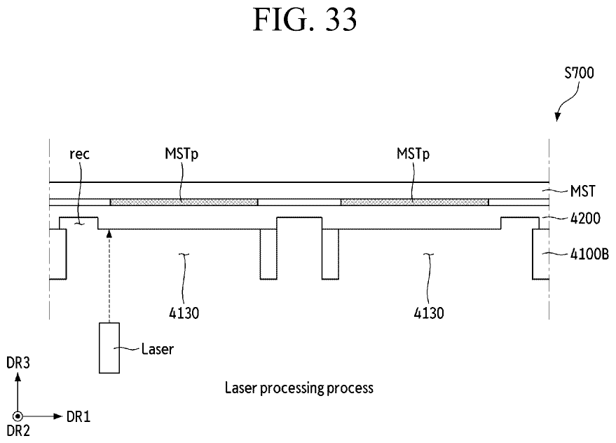

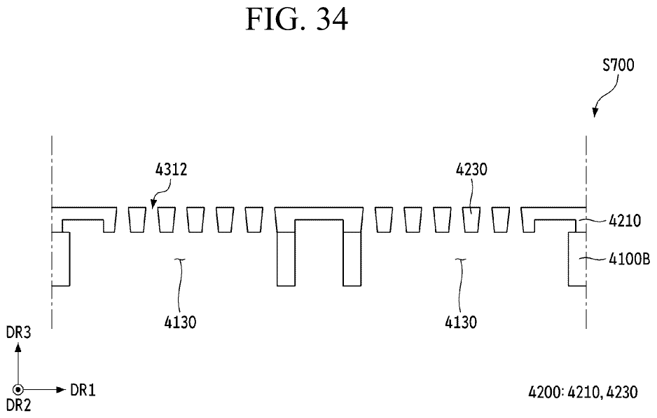

FIGS. 33 and 34 are cross-sectional views showing process S700 of FIG. 29.

The process of forming the pixel opening by laser processing the organic film (S700) will be described with reference to FIGS. 33 and 34 in addition to FIGS. 1 to 32.

First, the deposition mask 4000 is aligned with a master substate MST. Although not illustrated in the drawing, the master substrate MST and the deposition mask 4000 may each include an alignment key, and the above-described alignment key may be used to be aligned with each other.

In the present process, the master substrate MST may include a light emitting element pattern MSTp. In an embodiment, for example, the light emitting element pattern MSTp may include portions in which the areas are divided the same as the arrangement of the light emitting elements LE overlapping each of the first emission area EA1, the second emission area EA2, and the third emission area EA3 included in the display panel according to an embodiment.

In the present process, since the organic film 4200 according to an embodiment has a light transmittance of about 5 % or greater in the visible light range (about 380 nanometers or greater and about 680 nanometers or less), laser may be radiated onto the desired location to form the pixel opening 4312 with reference to the light emitting element pattern MSTp of the master substrate MST. Accordingly, the deposition mask 4000 according to an embodiment may have ease of manufacturing and manufacturing accuracy.

Subsequently, the laser is radiated from the second mask substrate 4100B toward the direction facing the organic film (i.e., one side of the third direction DR3) to perform a laser processing process. In the present process, the laser may be radiated on to the organic film 4200 overlapping the cell opening 4130 and may be radiated onto a portion not overlapping the recessed portion rec of the organic film 4200.

The laser processing process may be the same as the process described in FIG. 23. Any repetitive detailed description thereof will be omitted.

In the present process, the plurality of openings provided in the organic film 4200 may be formed to have a regular tapered shape or a trapezoidal shape. In other words, the plurality of openings provided in the organic film 4200 may have a greater width in a direction where the laser is radiated from. This may be for minimizing shadow defect due to the deposition mask 4000p when the deposition material moves passing through the cell opening 4130 and opening provided in the organic film 4200 during the subsequent process. Any repetitive detailed description thereof will be omitted.

In the present process, the organic film 4200 may be formed in a form of a support film 4210 located to overlap the mask substrate 4100 and a membrane 4230 spaced apart from the support film 4210 with the pixel opening 4312 therebetween.

In the present process, since the plurality of pixel openings 4312 may be formed to have a regular tapered shape or a trapezoidal shape, the plurality of membranes 4230 may have a reverse tapered shape.

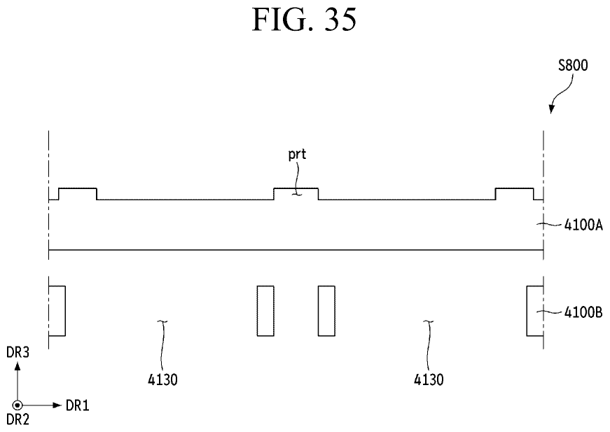

FIG. 35 is a cross-sectional view showing process S800 of FIG. 29.

Referring to FIG. 35, the process of removing and discarding the organic film after forming the deposition material on the semiconductor substrate (S800) will be described.

The present process may be the same as the ‘process of removing and discarding the organic film after forming the deposition material on the semiconductor substrate (S300)’ which is illustrated in FIGS. 25 to 27 and described. Any repetitive detailed description thereof will be omitted.

Through the present process, the organic film 4200 may be completely detached from the second mask substrate 4100B and the detached organic film 4200 may be discarded.

In present process, the first mask substrate 4110A and the second mask substrate 4100B may remain. The remaining first mask substrate 4110A and the second mask substrate 4100B may perform the manufacturing process of the deposition mask 4000p sequentially from ‘the process of attaching the organic film on the patterned first mask substrate (S500) of FIG. 29 and be reused.

As described above with reference to FIGS. 1 to 35, the deposition mask 4000p may use the organic film 4200 in the deposition process by attaching the organic film 4200 on the first mask substrate 4100A and the second mask substrate 4100B on the manufacturing process, and thereafter, detach the contaminated organic film 4200 to reuse the first mask substrate 4100A and the second mask substrate 4100B, thereby having the effect of ease of manufacturing and reducing the manufacturing cost.

In addition, the deposition mask 4000p may include a membrane 4230 of a reverse tapered shape, thereby minimizing a shadow defect due to the deposition mask 4000p during the manufacturing process.

Moreover, since the deposition mask 4000p uses the organic film 4200 including the recessed portion rec, an adhesion area of the mask substrate 4100 and the organic film 4200 may be minimized, and accordingly, detachment defect of the mask substrate 4100 and the organic film 4200 due to a film stress (film strain) of the organic film 4200 may be minimized.

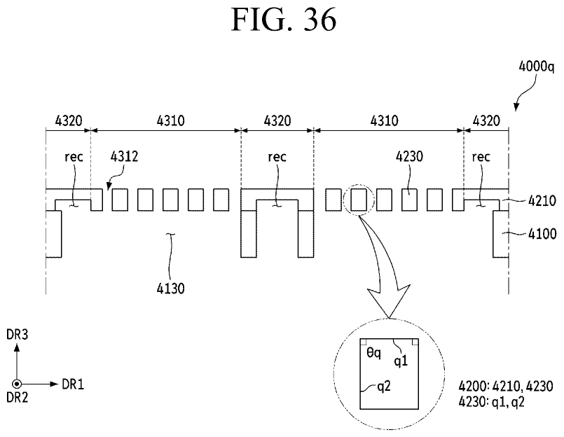

FIG. 36 is a schematic cross-sectional view of a deposition mask according to another embodiment taken along line I2-I2′ of FIG. 17.

Referring to FIG. 36 in addition to FIGS. 1 to 35, an embodiment of a deposition mask 4000q may include a mask substrate 4100 and an organic film 4200. In such an embodiment, the shape of the mask substrate 4100 included in the deposition mask 4000q may be the same as the shape of the mask substrate 4100 included in the deposition mask 4000p. However, the shape of the organic film 4200 included in the deposition mask 4000q may be different from the shape of the organic film 4200 included in the deposition mask 4000p.

The mask substrate 4100 included in the deposition mask 4000q may be located at a portion overlapping the mask cell region 4310 and the grid region 4320.

The mask substrate 4100 may include a silicon-based, silicon oxide-based, or aluminum oxide-based material having a coefficient of thermal expansion (CTE) of about zero (0) ppm/° C. or greater and about 3 ppm/° C. or less. In an embodiment, for example, the mask substrate 4100 may include at least one selected from silicon-based glass, borosilicate-based glass, silica-based glass, and ceramic glass. Any repetitive detailed description thereof will be omitted.

The mask substrate 4100 included in the deposition mask 4000q may be separately formed and attached after the laser process of the organic film 4200 during the manufacturing process of the deposition mask 4000q. Accordingly, the mask substrate 4100 included in the deposition mask 4000q may have various shapes corresponding to desired characteristics other than the illustrated shape.

Hereinafter, the common description of the deposition mask 4000p and the deposition mask 4000q will be omitted and differences will be described.

The organic film 4200 included in the deposition mask 4000q may be located on the mask substrate 4100. The organic film 4200 may be located to overlap the mask cell region 4310 and the grid region 4320.

Although it is illustrated in the drawing that an adhesive is not included between the organic film 4200 and the mask substrate 4100, the present disclosure is not limited thereto. According to embodiments, the organic film 4200 may be attached on the mask substrate 4100 using an organic adhesive.

The organic film 4200 included in the deposition mask 4000q may include the same material as and have the same thickness as the organic film 4200 included in the deposition mask 4000. Any repetitive detailed description will thereof be omitted.

In an embodiment, the organic film 4200 located at a portion overlapping the grid region 4320 may be located on the mask substrate 4100 and may be referred to as a support film 4210. In other words, the support film 4210 may be located to overlap the mask substrate 4100.

The support film 4210 included in the deposition mask 4000q may include a recessed portion rec at the central portion. As the support film 4320 includes the recessed portion rec, the deposition mask 4000q may minimize the contact area of the mask substrate 4100 and the organic film 4200. Accordingly, the deposition mask 4000q may minimize detachment defect from the mask substrate 4100 due to the film stress (film strain) of the organic film 4200. Any repetitive detailed description thereof will be omitted.

The organic film 4200 located at a portion overlapping the mask cell region 4310 may be referred to as a membrane 4230. The membrane 4230 may be spaced apart from the support film 4210 with the pixel opening 4312 therebetween. In a plan view, the membrane 4230 and the support film 4210 may be a single organic film pattern located to surround the pixel opening 4312 and be integrally formed as a single unitary indivisible part.

The pixel opening 4312 and cell opening 4130 may be located at a portion overlapping the mask cell region 4310. The pixel opening 4312 and the cell opening 4130 may be connected to each other to be in communication with each other.

The membrane 4230 included in the deposition mask 4000q may have a rectangular shape. The membrane 4230 included in the deposition mask 4000q may have an upper surface q1 and a side surface q2, and an inclination angle θq formed by the upper surface q1 and the side surface q2 may be about 90 degrees. However, the inclination angle θq may have a process error of 10 % or less.

In the deposition mask 4000q, laser may be radiated in the upper direction of the organic film 4200 to form the pixel opening 4312 during the manufacturing process. Accordingly, the membrane 4230 included in the deposition mask 4000q may have a rectangular shape. The manufacturing process will be described below.

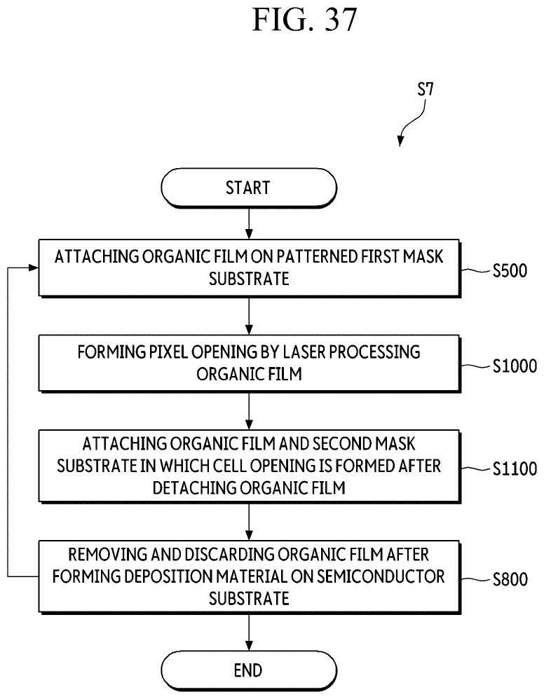

FIG. 37 is a flowchart showing a manufacturing method of a deposition mask illustrated in FIG. 36.

Referring to FIG. 37 in addition to FIGS. 1 to 36, a manufacturing method S7 of a deposition mask according to an embodiment may include a process of attaching an organic film on a patterned first mask substrate (S500), a process of forming a pixel opening by laser processing the organic film (S1000), a process of attaching the organic film and a second mask substrate in which cell opening is formed after detaching the organic film (S1100), and a process of removing and discarding the organic film after forming a deposition material on a semiconductor substrate (S800).

The process of attaching the organic film on the patterned first mask substrate (S500) of FIG. 37 is the same as the ‘process of attaching the organic film on the patterned first mask substrate (S500)’ illustrated and described in FIG. 30. Any repetitive detailed description thereof will be omitted.

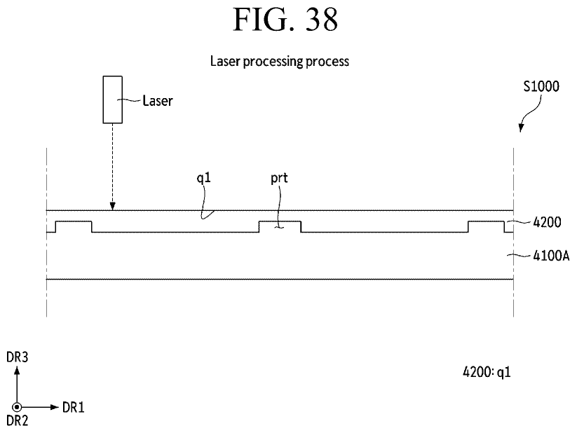

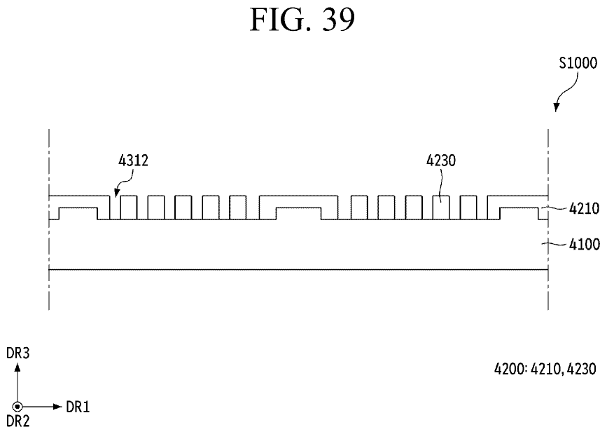

FIGS. 38 and 39 are cross-sectional views showing process S1000 of FIG. 37.

The process of forming the pixel opening by laser processing the organic film (S1000) will be described with reference to FIGS. 38 and 39.

First, a laser processing process is performed by radiating a laser in the upper surface q1 direction of the organic film 4200 attached on the first mask substrate 4100A including a plurality of protrusion portions prt. The laser processing process is the same as the process described in FIG. 23, except that the radiated direction is different. Any repetitive detailed description thereof will be omitted.

The present process may be performed by adjusting the laser process condition so that the plurality of openings provided in the organic film 4200 does not have a reverse tapered shape. Accordingly, in the present process, the plurality of openings provided in the organic film 4200 may have a rectangular shape. In the present process, the plurality of openings provided in the organic film 4200 may be referred to as the pixel opening 4312.

In the present process, the organic film 4200 may be formed in a form of a support film 4210 and a membrane 4230 spaced apart from the support film 4210 with the pixel opening 4312 therebetween.

As the plurality of pixel openings 4312 are formed to have a rectangular shape in the present process, the plurality of membranes 4230 may have a rectangular shape.

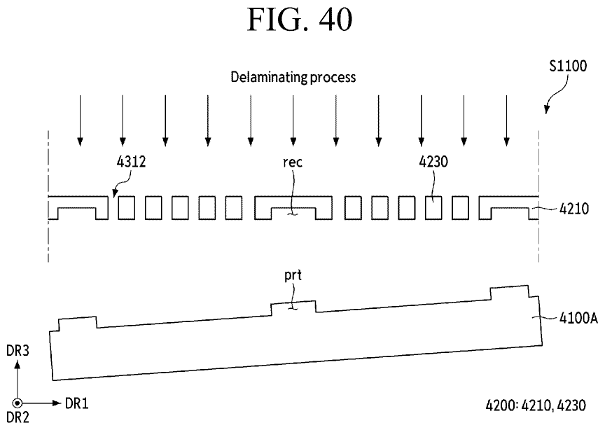

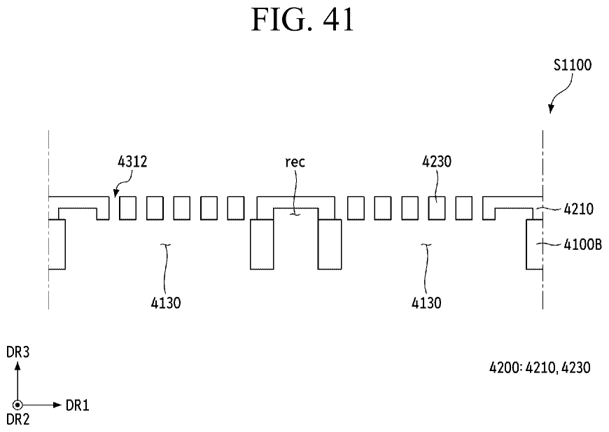

FIGS. 40 and 41 are cross-sectional views showing process S1100 of FIG. 37.

The process of attaching the organic film and the second mask substrate in which the cell opening is formed after detaching the organic film (S1100) will be described with reference to FIGS. 40 and 41 in addition to FIGS. 1 to 39.

First, a delaminating process is performed. In the present process, the organic film 4200 may be separated from the first mask substrate 4100A. In the present process, the organic film 4200 may be detached without any damaged portion.

The delaminating process performed in the present process may be performed through a thermal method, a mechanical method, and a laser method. Any repetitive detailed description thereof will be omitted.

Through the present process, the organic film 4200 may be completely detached from the first mask substrate 4100A, and the shape of the organic film 4200 may remain as the same as the shape before the delaminating process.

In the present process, the first mask substrate 4100A separated from the organic film 4200 may be reused after going through subsequent processes such as residue treatment, surface treatment, and drying.

In the present process, the organic film 4200 may be formed in a shape including a plurality of recess portions rec. The plurality of recessed portions rec included in the organic film 4200 may be formed to correspond to the plurality of protrusion portions prt included in the first mask substrate 4100A.

Subsequently, a second mask substrate 4100B patterned to have the cell opening 4130 is attached on the organic film 4200. The second mask substrate 4100B may be a different substrate separate from the first mask substrate 4100A. The present process may be performed through a laminating process. Any repetitive detailed description thereof will be omitted.

The support film 4210 included in the deposition mask 4000q may include a recessed portion rec, and accordingly, the deposition mask 4000q may minimize the adhesion area of the support film 4210 and the second mask substrate 4100B. The second mask substrate 4100B may be referred to as the mask substrate 4100 in FIG. 36.

Subsequently, the process of removing and discarding the organic film after forming the deposition material on the semiconductor substrate (S800) of FIG. 37 is performed. The present process may be the same as the ‘process of removing and discarding the organic film after forming the deposition material on the semiconductor substrate (S800)’ of FIG. 35. Any repetitive detailed description thereof will be omitted.

In the present process, the first mask substrate 4110A and the second mask substrate 4100B may remain. The remaining first mask substrate 4110A and the second mask substrate 4100B may perform the manufacturing process of the deposition mask 4000q sequentially from ‘the process of attaching the organic film on the patterned first mask substrate (S500)’of FIG. 37 and be reused.

In such an embodiment, as described above with reference to FIGS. 1 to 41, the deposition mask 4000q may use the organic film 4200 in the deposition process by attaching the organic film 4200 on the first mask substrate 4100A and the second mask substrate 4100B on the manufacturing process, and thereafter, detach the contaminated organic film 4200 to reuse the first mask substrate 4100A and the second mask substrate 4100B, thereby having the effect of manufacturing ease and reducing the manufacturing cost.

Moreover, since the deposition mask 4000q uses the organic film 4200 including the recessed portion rec, an adhesion area of the mask substrate 4100 and the organic film 4200 may be minimized, and accordingly, detachment defect of the mask substrate 4100 and the organic film 4200 due to a film stress (film strain) of the organic film 4200 may be minimized.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A deposition mask comprising:
a mask substrate provided with a cell opening defined therethrough; and
an organic film comprising a support film overlapping the mask substrate and a membrane spaced apart from the support film with a pixel opening therebetween,
wherein the organic film includes an organic material,
the mask substrate includes at least one selected from silicon nitride-based, silicon carbide-based, borosilicate-based, silicon oxide-based or aluminum oxide-based material, and
a coefficient of thermal expansion of the mask substrate is about zero (0) ppm/° C. or greater and about 3 ppm/° C. or less.

2. The deposition mask of claim 1,
wherein the mask substrate includes an upper surface facing the organic film and a side surface facing the cell opening, and
a first inclination angle formed by the side surface and the upper surface is about 50 degrees or greater and about 90 degrees or less.

3. The deposition mask of claim 2,
wherein the membrane has a reverse tapered shape,
the membrane includes an upper surface located in an opposite direction to a direction where the mask substrate is located and a side surface facing the pixel opening, and
a second inclination angle formed by the upper surface and the side surface of the membrane is about 50 degrees or greater and about 80 degrees or less.

4. The deposition mask of claim 1,
wherein a thickness of the organic film is about 1 micrometer or greater and about 10 micrometer or less, and
the thickness of the organic film has a thickness uniformity of about 10 % or less.

5. The deposition mask of claim 4,
wherein the organic film has a light transmittance of about 5% or greater in a visible light range of about 380 nanometers to about 680 nanometers.

6. The deposition mask of claim 5,
wherein the organic film includes at least one selected from polyvinyl alcohol, polyimide, or acrylic.

7. The deposition mask of claim 1,
wherein, in a plan view, the organic film is an organic pattern form defining a plurality of pixel openings.

8. The deposition mask of claim 1,
wherein the support film includes a recessed portion recessed in a direction perpendicular to one surface of the mask substrate, and
a portion of the support film overlapping the recessed portion does not overlap the mask substrate.

9. A manufacturing method of a deposition mask, the method comprising:
forming a cell opening by removing a portion of a mask substrate;
forming a pixel opening by laser processing after attaching an organic film on the mask substrate; and
removing and discarding the organic film after forming a deposition material on a semiconductor substrate.

10. The method of claim 9,
wherein, in the forming the cell opening by removing the portion of the mask substrate,
the mask substrate includes an upper surface facing the organic film and a side surface facing the cell opening, and
a first inclination angle formed by the upper surface and the side surface is about 50 degrees or greater and about 90 degrees or less.

11. The method of claim 10,
wherein, in the forming of the cell opening by removing the portion of the mask substrate,
the mask substrate includes at least one selected from silicon nitride-based, silicon carbide-based, borosilicate-based, silicon oxide-based or aluminum oxide-based material,
and a coefficient of thermal expansion of the mask substrate is about zero (0) ppm/° C. or greater and about 3 ppm/° C. or less.

12. The method of claim 9,
wherein, in the forming of the pixel opening by laser processing after the attaching the organic film on the mask substrate,
the mask substrate is performed by aligning with a master substrate including a light emitting element pattern, and
the light emitting element pattern of the mask substrate includes a same alignment as an alignment of an emission area of a display panel.

13. The method of claim 12,
wherein the pixel opening is formed by radiating a laser onto the organic film,
the pixel opening is located at a portion overlapping the light emitting element pattern, and
the laser is radiated from a direction where a lower surface of the mask substrate is located to a direction facing the organic film.

14. The method of claim 13,
wherein the cell opening and the pixel opening are connected to and in communication with each other, and
the pixel opening has a shape of a regular tapered shape or a trapezoidal shape.

15. The method of claim 9,
wherein, in the forming the pixel opening by laser processing after the attaching the organic film on the mask substrate,
the organic film is divided into a support film overlapping the mask substrate and a membrane spaced apart from the support film with a pixel opening therebetween,
the membrane includes an upper surface located in an opposite direction to a direction where the mask substrate is located and a side surface facing the pixel opening, and
a second inclination angle formed by the upper surface and the side surface is about 50 degrees or greater and about 80 degrees or less.

16. The method of claim 9,
wherein, in the removing and discarding the organic film after the forming the deposition material on the semiconductor substrate,
the organic film is completely removed from the mask substrate, and
the mask substrate is reused after washing and surface treatment processes.

17. An electronic device comprising:
a display panel including a deposition material formed by using a deposition mask on a semiconductor substrate;
a display device including the display panel; and
at least one selected from a processor, a memory, or a power module, which are connected to the display device,
wherein the deposition mask comprises:
a mask substrate provided with a cell opening defined therethrough; and
an organic film comprising a support film overlapping the mask substrate, and a membrane spaced apart from the support film with a pixel opening therebetween,
the organic film includes an organic material,
the mask substrate includes at least one selected from silicon nitride-based, silicon carbide-based, borosilicate-based, silicon oxide-based or aluminum oxide-based material,
but a coefficient of thermal expansion of the mask substrate is 0 ppm/° C. or more and 3 ppm/° C. or less.

18. The electronic device of claim 17,
wherein the mask substrate includes an upper surface facing the organic film and a side surface facing the cell opening,
a first inclination angle formed by the side surface and the upper surface of the mask substrate is about 50 degrees or greater and about 90 degrees or less,
the membrane has a reverse tapered shape,
the membrane includes an upper surface located in an opposite direction to a direction where the mask substrate is located and a side surface facing the pixel opening, and
a second inclination angle formed by the upper surface and the side surface of the membrane is about 50 degrees or greater and about 80 degrees or less.

19. The electronic device of claim 17,
wherein the thickness of the organic film is about 1 micrometer or greater and about 10 micrometer or less, and
the organic film has a light transmittance of about 5% or greater in a visible light range of about 380 nanometers to about 680 nanometers.

20. The electronic device of claim 19,
wherein the organic film includes at least one selected from polyvinyl alcohol, polyimide, or acrylic, and
in a plan view, the organic film is an organic pattern form defining a plurality of pixel openings.
